(19) United States
(12) Patent Application Publication
(10) Pub. No.: US 2023/0341778 A1
(43) Pub. Date: Oct. 26, 2023

(54) METHOD FOR MANUFACTURING SEMICONDUCTOR SUBSTRATE AND COMPOSITION

(71) Applicant: JSR CORPORATION, Tokyo (JP)

(72) Inventors: Naoya NOSAKA, Tokyo (JP); Kengo EHARA, Tokyo (JP); Hiroki NAKATSU, Tokyo (JP); Masato DOBASHI, Tokyo (JP); Hiroyuki MIYAUCHI, Tokyo (JP)

(73) Assignee: JSR CORPORATION, Tokyo (JP)

(21) Appl. No.: 18/209,751

(22) Filed: Jun. 14, 2023

Related U.S. Application Data
(63) Continuation-in-part of application No. PCT/JP2021/048213, filed on Dec. 24, 2021.

(30) Foreign Application Priority Data
Dec. 28, 2020 (JP) 2020-218912

(51) Int. Cl. G03F 7/11; G03F 7/09; G03F 7/38; H01L 21/311

(52) U.S. Cl. CPC G03F 7/11; G03F 7/094; G03F 7/38; H01L 21/31138; H01L 21/31144

(57) ABSTRACT

A method for manufacturing a semiconductor substrate includes forming a resist underlayer film directly or indirectly on a substrate by applying a composition. The composition includes a compound and a solvent. The compound includes: at least one nitrogen-containing ring structure selected from the group consisting of a pyridine ring structure and a pyrimidine ring structure; and a partial structure represented by formula (1-1) or (1-2). X¹ and X² are each independently a group represented by formula (i), (ii), (iii), or (iv); * is a bond with a moiety of the compound other than the partial structure represented by formula (1-1) or (1-2); and Ar¹¹ and Ar¹² are each independently a substituted or unsubstituted aromatic ring having 5 to 20 ring members that forms a fused ring structure together with the two adjacent carbon atoms in the formulas (1-1) and (1-2).

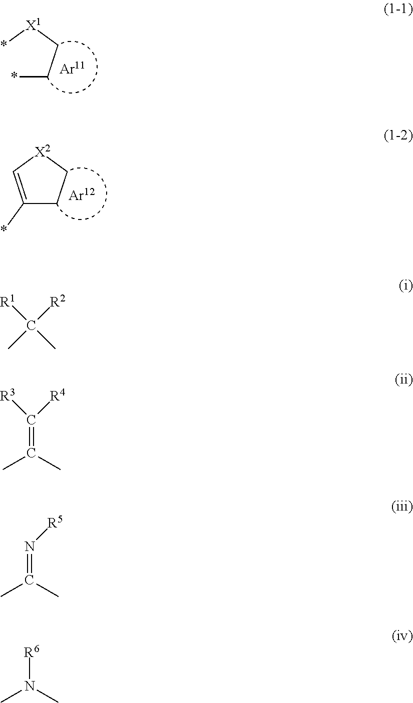

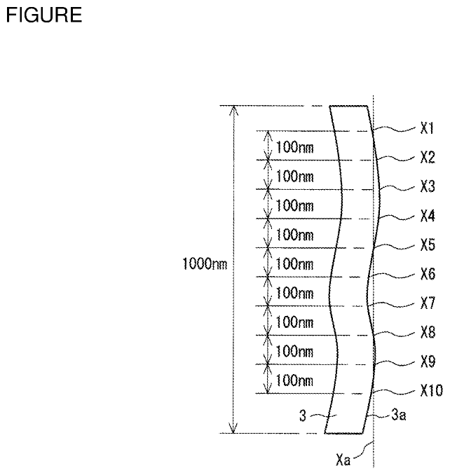

### CROSS-REFERENCE TO RELATED APPLICATIONS

The present application is a continuation-in-part application of PCT/JP2021/048213 filed Dec. 24, 2021, which claims priority to Japanese Patent Application No. 2020-218912 filed Dec. 28, 2020. The contents of these applications are incorporated herein by reference in their entirety.

### BACKGROUND OF THE DISCLOSURE

### Technical Field

The present disclosure relates to a method for manufacturing a semiconductor substrate and a composition.

### Description of the Related Art

A semiconductor device is produced using, for example, a multilayer resist process in which a resist pattern is formed by exposing and developing a resist film laminated on a substrate with a resist underlayer film, such as an organic underlayer film or a silicon-containing film, being interposed between them. In this process, the resist underlayer film is etched using this resist pattern as a mask, and the substrate is further etched using the obtained resist underlayer film pattern as a mask so that a desired pattern is formed on the semiconductor substrate (see JP-A-2004-177668).

Various studies have been conducted on materials to be used for such a composition for forming a resist underlayer film (see WO 2011/108365 A).

### SUMMARY OF THE DISCLOSURE

According to an aspect of the present disclosure, a method for manufacturing a semiconductor substrate includes forming a resist underlayer film directly or indirectly on a substrate by applying a composition for forming a resist underlayer film. A resist pattern is formed directly or indirectly on the resist underlayer film. Etching is performed using the resist pattern as a mask. The composition for forming a resist underlayer film includes a compound and a solvent. The compound includes: at least one nitrogen-containing ring structure selected from the group consisting of a pyridine ring structure and a pyrimidine ring structure; and a partial structure represented by formula (1-1) or (1-2).

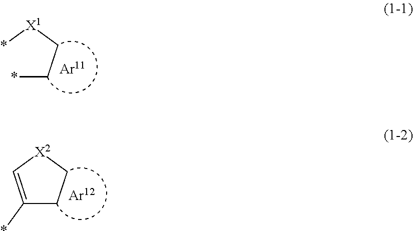

In the formulas (1-1) and (1-2), X¹ and X² are each independently a group represented by formula (i), (ii), (iii), or (iv); * is a bond with a moiety of the compound other than the partial structure represented by formula (1-1) or (1-2); and Ar¹¹ and Ar¹² are each independently a substituted or unsubstituted aromatic ring having 5 to 20 ring members that forms a fused ring structure together with the two adjacent carbon atoms in the formulas (1-1) and (1-2),

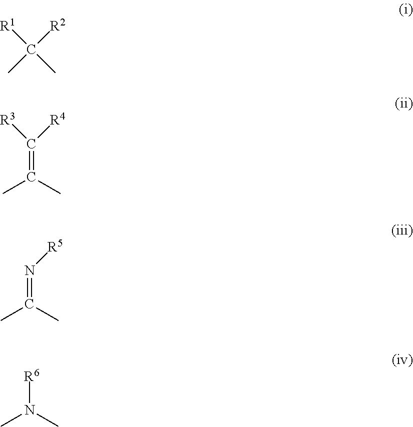

In the formula (i), R¹ and R² are each independently a hydrogen atom or a monovalent organic group having 1 to 20 carbon atoms; in the formula (ii), R³ and R⁴ are each independently a hydrogen atom or a monovalent organic group having 1 to 20 carbon atoms; in the formula (iii), R⁵ is a monovalent organic group having 1 to 20 carbon atoms; and in the formula (iv), R⁶ is a hydrogen atom or a monovalent organic group having 1 to 20 carbon atoms.

According to another aspect of the present disclosure, a composition includes a compound and a solvent. The compound includes: at least one nitrogen-containing ring structure selected from the group consisting of a pyridine ring structure and a pyrimidine ring structure; and a partial structure represented by formula (1-1) or (1-2).

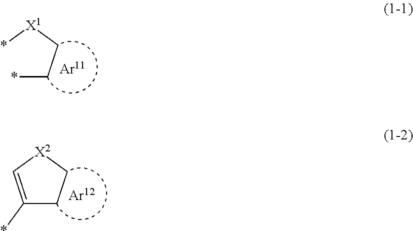

In the formulas (1-1) and (1-2), X¹ and X² are each independently a group represented by formula (i), (ii), (iii), or (iv); * is a bond with a moiety of the compound other than the partial structure represented by formula (1-1) or (1-2); and Ar¹¹ and Ar¹² are each independently a substituted or unsubstituted aromatic ring having 5 to 20 ring members that forms a fused ring structure together with the two adjacent carbon atoms in the formulas (1-1) and (1-2).

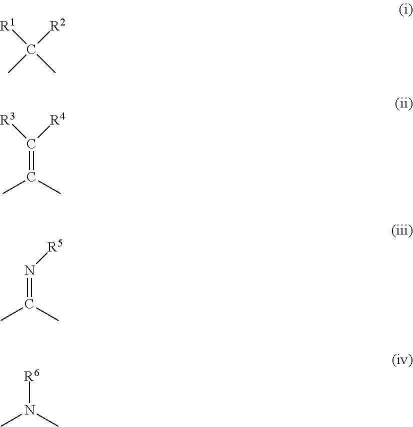

In the formula (i), R¹ and R² are each independently a hydrogen atom or a monovalent organic group having 1 to 20 carbon atoms; in the formula (ii), R³ and R⁴ are each independently a hydrogen atom or a monovalent organic group having 1 to 20 carbon atoms; R⁴ is a monovalent organic group having 1 to 20 carbon atoms; in the formula (iii), R⁵ is a monovalent organic group having 1 to 20 carbon atoms; and in the formula (iv), R⁶ is a hydrogen atom or a monovalent organic group having 1 to 20 carbon atoms.

### BRIEF DESCRIPTION OF THE DRAWINGS

The FIG. is a schematic plan view for explaining a method of evaluating bending resistance.

### DETAILED DESCRIPTION OF THE PREFERRED EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

In a multilayer resist process, an organic underlayer film as a resist underlayer film is required to have etching resistance, heat resistance, and bending resistance.

The present disclosure relates, in one embodiment, to a method for manufacturing a semiconductor substrate, the method including:
applying a composition for forming a resist underlayer film directly or indirectly to a substrate;
forming a resist pattern directly or indirectly on a resist underlayer film formed in the applying step; and
performing etching using the resist pattern as a mask,
wherein the composition for forming a resist underlayer film includes:
a compound containing at least one nitrogen-containing ring structure selected from the group consisting of a pyridine ring structure and a pyrimidine ring structure, and a partial structure represented by formula (1-1) or (1-2) (hereinafter, the compound is also referred to as “compound [A]”); and
a solvent (hereinafter, the solvent is also referred to as “solvent [B]”),

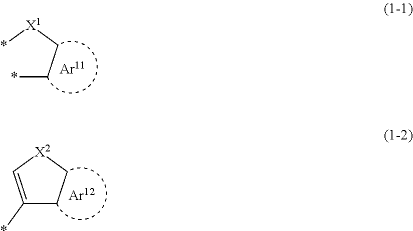

in the formulas (1-1) and (1-2), X¹ and X² are each independently a group represented by formula (i), (ii), (iii) or (iv); * is a bond with a moiety of the compound other than the partial structure represented by formula (1-1) or (1-2); and Ar¹¹ and Ar¹² are each independently a substituted or unsubstituted aromatic ring having 5 to 20 ring members that forms a fused ring structure together with two adjacent carbon atoms in the formulas (1-1) and (1-2),

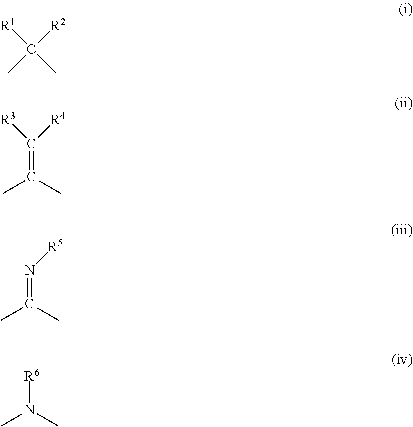

in the formula (i), R¹ and R² are each independently a hydrogen atom or a monovalent organic group having 1 to 20 carbon atoms;

in the formula (ii), R³ and R⁴ are each independently a hydrogen atom or a monovalent organic group having 1 to 20 carbon atoms;

in the formula (iii), R⁵ is a monovalent organic group having 1 to 20 carbon atoms; and

in the formula (iv), R⁶ is a hydrogen atom or a monovalent organic group having 1 to 20 carbon atoms.

In the present specification, the term “ring members” refers to the number of atoms constituting the ring. For example, a biphenyl ring has 12 ring members, a naphthalene ring has 10 ring members, and a fluorene ring has 13 ring members. The term “fused ring structure” refers to a structure in which adjacent rings share one side (two adjacent atoms). The term “organic group” refers to a group containing at least one carbon atom.

The present disclosure relates, in another embodiment, to a composition including:
a compound containing at least one nitrogen-containing ring structure selected from the group consisting of a pyridine ring structure and a pyrimidine ring structure, and a partial structure represented by formula (1-1) or (1-2); and
a solvent.

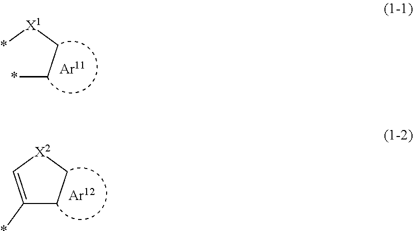

in the formulas (1-1) and (1-2), X¹ and X² are each independently a group represented by formula (i), (ii), (iii) or (iv); * is a bond with a moiety of the compound other than the partial structure represented by formula (1-1) or (1-2); and Ar¹¹ and Ar¹² are each independently a substituted or unsubstituted aromatic ring having 5 to 20 ring members that forms a fused ring structure together with two adjacent carbon atoms in the formulas (1-1) and (1-2),

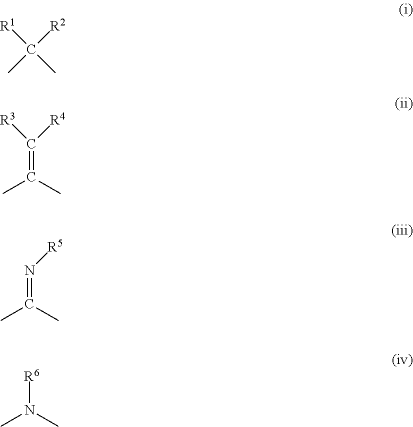

in the formula (i), R¹ and R² are each independently a hydrogen atom or a monovalent organic group having 1 to 20 carbon atoms;

in the formula (ii), R³ and R⁴ are each independently a hydrogen atom or a monovalent organic group having 1 to 20 carbon atoms;

in the formula (iii), R⁵ is a monovalent organic group having 1 to 20 carbon atoms; and

in the formula (iv), R⁶ is a hydrogen atom or a monovalent organic group having 1 to 20 carbon atoms.

According to the method for manufacturing a semiconductor substrate, since a resist underlayer film superior in etching resistance, heat resistance, and bending resistance is formed, a favorable semiconductor substrate can be obtained. When the composition is used, a film superior in etching resistance, heat resistance, and bending resistance can be formed. Therefore, they can suitably be used for, for example, producing semiconductor devices expected to be further microfabricated in the future.

Hereinafter, a method for manufacturing a semiconductor substrate and a composition according to embodiments of the present disclosure will be described in detail.

### <<Method for Manufacturing Semiconductor Substrate>>

The method for manufacturing a semiconductor substrate includes:
applying a composition for forming a resist underlayer film directly or indirectly to a substrate (hereinafter also referred to as an “applying step”);
forming a resist pattern directly or indirectly on the resist underlayer film formed by the applying step (hereinafter also referred to as a “resist pattern forming step”); and
performing etching using the resist pattern as a mask (hereinafter also referred to as an “etching step”).

According to the method for manufacturing a semiconductor substrate, a resist underlayer film superior in etching resistance, heat resistance, and bending resistance can be formed due to the use of a prescribed composition for forming a resist underlayer film in the applying step, and bending resistance can be formed, so that a semiconductor substrate having a favorable pattern configuration can be manufactured.

The method for manufacturing a semiconductor substrate may further include, as necessary, heating the resist underlayer film at 250° C. or higher before forming the resist pattern (hereinafter, also referred to as “heating step”).

The method for manufacturing a semiconductor substrate may further include, as necessary, forming a silicon-containing film directly or indirectly on the resist underlayer film before forming the resist pattern (hereinafter, also referred to as “silicon-containing film forming step”).

Hereinafter, the composition for forming a resist underlayer film to be used in the method for manufacturing a semiconductor substrate and the respective steps will be described.

### [Composition for Forming Resist Underlayer Film]

The composition for forming a resist underlayer film includes a compound [A] and a solvent [B]. The composition for forming a resist underlayer film may include an optional component as long as the effect of the composition is not impaired. Owing to containing the compound [A], the composition for forming a resist underlayer film can form a film superior in etching resistance, heat resistance, and bending resistance. Accordingly, this composition for forming a resist underlayer film can be suitably used in a multilayer resist process.

### <Compound [A]>

The compound [A] contains at least one nitrogen-containing ring structure selected from the group consisting of a pyridine ring structure and a pyrimidine ring structure, and a partial structure represented by formula (1-1) or (1-2). The composition for forming a resist underlayer film can contain one kind or two or more kinds of the compound [A].

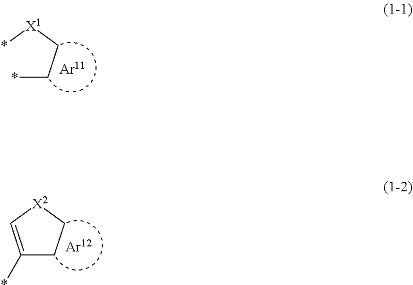

in the formulas (1-1) and (1-2), X¹ and X² are each independently a group represented by formula (i), (ii), (iii) or (iv); * is a bond with a moiety of the compound other than the partial structure represented by formula (1-1) or (1-2); and Ar¹¹ and Ar¹² are each independently a substituted or unsubstituted aromatic ring having 5 to 20 ring members that forms a fused ring structure together with two adjacent carbon atoms in the formulas (1-1) and (1-2),

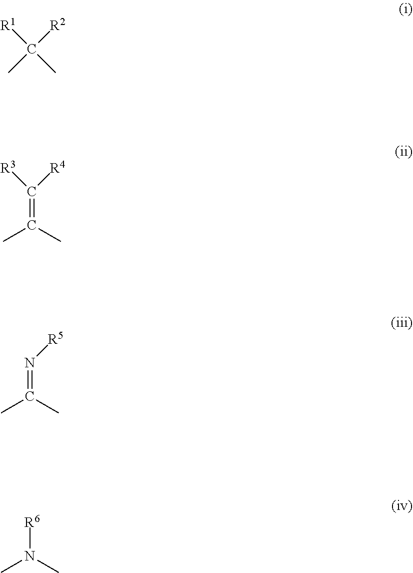

in the formula (i), R¹ and R² are each independently a hydrogen atom or a monovalent organic group having 1 to 20 carbon atoms;

in the formula (ii), R³ and R⁴ are each independently a hydrogen atom or a monovalent organic group having 1 to 20 carbon atoms;

in the formula (iii), R⁵ is a monovalent organic group having 1 to 20 carbon atoms; and

in the formula (iv), R⁶ is a hydrogen atom or a monovalent organic group having 1 to 20 carbon atoms.

### (Nitrogen-Containing Ring Structure)

The compound [A] contains at least one nitrogen-containing ring structure selected from the group consisting of a pyridine ring structure and a pyrimidine ring structure. However, the case where the nitrogen-containing ring structure is a partial structure represented by the above formula (1-1) or (1-2) is excluded. The number of the nitrogen-containing ring structures in the compound [A] may be 1 or 2 or more. The mode of containing the nitrogen-containing ring structure may be any one of a mode in which a ring structure that serves as a basis of the nitrogen-containing ring structure (namely, a pyridine ring and a pyrimidine ring) is independently contained, a mode in which a plurality of ring structures are linked like bipyridine or the like, a mode in which a fused ring structure is formed with another ring structure such as an alicyclic structure or an aromatic ring structure, and a combination thereof. From the viewpoint of the ease of synthesis, the heat resistance, and the like of the compound [A], a pyridine ring structure is preferable as the ring structure.

The nitrogen-containing ring structure may have a substituent. Examples of the substituent include monovalent chain hydrocarbon groups having 1 to 10 carbon atoms, halogen atoms such as a fluorine atom, a chlorine atom, a bromine atom, and an iodine atom, alkoxy groups such as a methoxy group, an ethoxy group, and a propoxy group, alkoxycarbonyl groups such as a methoxycarbonyl group and an ethoxycarbonyl group, alkoxycarbonyloxy groups such as a methoxycarbonyloxy group and an ethoxycarbonyloxy group, acyl groups such as a formyl group, an acetyl group, a propionyl group, and a butyryl group, a cyano group, and a nitro group.

### (Partial Structure)

The partial structure is represented by the above formula (1-1) or (1-2). The lower limit of the number of the partial structures in the compound [A] is 1, and preferably 2. The upper limit of the number of the partial structures is not particularly limited, and is preferably 10, and more preferably 6. When the compound [A] has two or more partial structures, the plurality of partial structures are the same or different from each other.

In the formulas (1-1) and (1-2), X¹ and X² are each independently a group represented by formula (i), (ii), (iii), or (iv).

Examples of the monovalent organic groups having 1 to 20 represented by R¹, R², R³, R⁴, R⁵, and R⁶ in the formulas (i), (ii), (iii), and (iv) include a monovalent hydrocarbon group having 1 to 20 carbon atoms, a group containing a divalent heteroatom-containing group between two carbon atoms of the foregoing hydrocarbon group, a group obtained by substituting some or all of the hydrogen atoms of the foregoing hydrocarbon group with a monovalent heteroatom-containing group, and a combination thereof.

Examples of the monovalent hydrocarbon group having 1 to 20 carbon atoms include monovalent chain hydrocarbon groups having 1 to 20 carbon atoms, monovalent alicyclic hydrocarbon groups having 4 to 20 carbon atoms, monovalent aromatic hydrocarbon groups having 6 to 20 carbon atoms, and combinations thereof.

As used herein, the “hydrocarbon group” includes a chain hydrocarbon group, an alicyclic hydrocarbon group, and an aromatic hydrocarbon group. The “hydrocarbon group” includes a saturated hydrocarbon group and an unsaturated hydrocarbon group. The “chain hydrocarbon group” means a hydrocarbon group that contains no cyclic structure and is composed only of a chain structure, and includes both a linear hydrocarbon group and a branched hydrocarbon group. The “alicyclic hydrocarbon group” means a hydrocarbon group that contains only an alicyclic structure as a ring structure and contains no aromatic ring structure, and includes both a monocyclic alicyclic hydrocarbon group and a polycyclic alicyclic hydrocarbon group (however, the alicyclic hydrocarbon group is not required to be composed of only an alicyclic structure, and may contain a chain structure as a part thereof). The “aromatic hydrocarbon group” means a hydrocarbon group containing an aromatic ring structure as a ring structure (however, the aromatic hydrocarbon group is not required to be composed of only an aromatic ring structure, and may contain an alicyclic structure or a chain structure as a part thereof).

Examples of the monovalent chain hydrocarbon group having 1 to 20 carbon atoms include alkyl groups such as a methyl group, an ethyl group, a n-propyl group, an i-propyl group, a n-butyl group, a sec-butyl group, a tert-butyl group; alkenyl groups such as an ethenyl group, a propenyl group and a butenyl group; and alkynyl groups such as an ethynyl group, a propynyl group and a butynyl group.

Examples of the monovalent alicyclic hydrocarbon group having 3 to 20 carbon atoms include cycloalkyl groups such as a cyclopentyl group and a cyclohexyl group; cycloalkenyl groups such as a cyclopropenyl group, a cyclopentenyl group, and a cyclohexenyl group; bridged cyclic saturated hydrocarbon groups such as a norbornyl group, an adamantyl group, and a tricyclodecyl group; and bridged cyclic unsaturated hydrocarbon groups such as a norbornenyl group and a tricyclodecenyl group.

Examples of the monovalent aromatic hydrocarbon group having 6 to 20 carbon atoms include a phenyl group, a tolyl group, a naphthyl group, an anthracenyl group, and a pyrenyl group.

Examples of heteroatoms that constitute divalent or monovalent heteroatom-containing groups include an oxygen atom, a nitrogen atom, a sulfur atom, a phosphorus atom, a silicon atom, and halogen atoms. Examples of the halogen atoms include a fluorine atom, a chlorine atom, a bromine atom, and an iodine atom.

Examples of the divalent heteroatom-containing group include —CO—, —CS—, —NH—, —O—, —S—, and groups obtained by combining them.

Examples of the monovalent heteroatom-containing group include a hydroxy group, a sulfanyl group, a cyano group, a nitro group, and halogen atoms.

In the above formulas (1-1) and (1-2), Ar¹¹ and Ar¹² are each independently a substituted or unsubstituted aromatic ring having 5 to 20 ring members that forms a fused ring structure together with two adjacent carbon atoms in the formulas (1-1) and (1-2). Examples of the aromatic ring having 5 to 20 ring members in Ar¹¹ and Ar¹² include aromatic hydrocarbon rings such as a benzene ring, a naphthalene ring, an anthracene ring, an indene ring, a pyrene ring, and a fluorene ring; and aromatic heterocycles such as a furan ring, a pyrrole ring, a thiophene ring, a phosphole ring, a pyrazole ring, an oxazole ring, an isoxazole ring, a thiazole ring, a pyridine ring, a pyrazine ring, a pyrimidine ring, and a pyridazine ring. The pyridine ring and the pyrimidine ring in Ar¹¹ and Ar¹² may exist as a constituent element of the nitrogen-containing ring structure of the compound [A], or may exist as a constituent element separate from the nitrogen-containing ring structure. The compound [A] as a whole is just required to contain the nitrogen-containing ring structure.

Examples of the substituent in Ar¹¹ and Ar¹² include the same substituents as the substituent of the nitrogen-containing ring structure.

The compound [A] preferably has at least one selected from the group consisting of a group represented by formula (X-1) and a group represented by formula (X-2). The lower limit of the total number of the group represented by formula (X-1) and the group represented by formula (X-2) in the compound [A] is preferably 1, more preferably 2, and still more preferably 3. The upper limit of the total number is preferably 10, more preferably 8, and still more preferably 6. In particular, the compound preferably has at least one group represented by formula (X-1). Owing to this, the heat resistance of a resulting resist underlayer film can be improved.

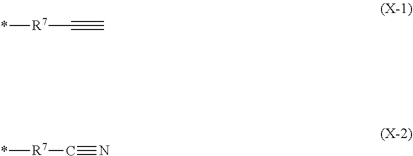

(In the formulas (X-1) and (X-2), R⁷ is each independently a divalent hydrocarbon group having 1 to 18 carbon atoms or a single bond. * is a bond with a carbon atom in the compound.)

Examples of the divalent hydrocarbon group having 1 to 18 carbon atoms represented by R⁷ in the formulas (X-1) and (X-2) include groups each obtained by removing one hydrogen atom from a group corresponding to 1 to 18 carbon atoms among the monovalent hydrocarbon groups in R¹, R², R³, R⁴, R⁵, and R⁶ in the above formulas (i), (ii), (iii), and (iv). Among them, R⁷ is preferably a divalent hydrocarbon group having 1 to 10 carbon atoms, and particularly preferably a methanediyl group, an ethanediyl group, a phenylene group, or a combination thereof.

The group represented by formula (X-1) or (X-2) is preferably included in X¹ or X² in the partial structure represented by formula (1-1) or (1-2). It is preferable that at least one of R¹ and R² in the formula (i), at least one of R³ and R⁴ in the formula (ii), R⁵ in the formula (iii) and R⁶ in the formula (iv) are each independently a group represented by formula (X-1) or (X-2).

The compound [A] is preferably represented by formula (2-1), (2-2), or (2-3).

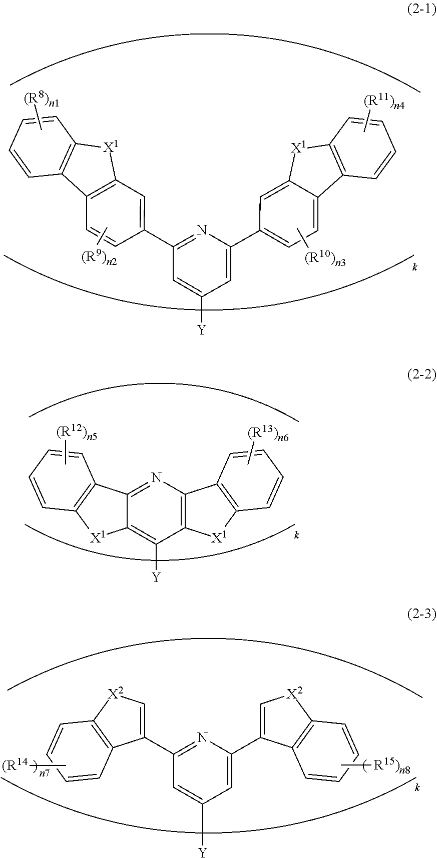

(In the formulas (2-1), (2-2), and (2-3), X¹ and X² have the same meanings as the above formulas (1-1) and (1-2), respectively. R⁸, R⁹, R¹⁰, R¹¹, R¹², R¹³, R¹⁴, and R¹⁵ are each independently a monovalent organic group having 1 to 10 carbon atoms. When R⁸, R⁹, R¹⁰, R¹¹, R¹², R¹³, R¹⁴, and R¹⁵ are each present in a plurality of numbers, the plurality of R⁸, R⁹, R¹⁰, R¹¹, R¹², R¹³, R¹⁴, and R¹⁵ are the same or different from each other. n₁, n₄, n₅, n₆, n₇, and n₈ are each independently an integer of 0 to 4, and n₂ and n₃ are each independently an integer of 0 to 3. k is independently at each occurrence 1 or 2. Y is a monovalent organic group having 1 to 20 carbon atoms.)

Examples of the monovalent organic group having 1 to 10 carbon atoms represented by R⁸, R⁹, R¹⁰, R¹¹, R¹², R¹³, R¹⁴, and R¹⁵ in the above formulas (2-1), (2-2), and (2-3) include a group corresponding to 1 to 10 carbon atoms among the monovalent organic groups having 1 to 20 carbon atoms represented by R¹, R², R³, R⁴, R⁵, and R⁶ in the above formulas (i), (ii), (iii), and (iv).

n₁, n₄, n₅, n₆, n₇ and n₈ are each independently preferably an integer of 0 to 2, more preferably 0 or 1, and still more preferably 0. n₂ and n₃ are each independently preferably an integer of 0 to 2, more preferably 0 or 1, and still more preferably 0. k is preferably 1.

Examples of the k-valent organic group having 1 to 20 carbon atoms represented by Y in the formulas (2-1), (2-2), and (2-3) include monovalent organic groups having 1 to 20 carbon atoms represented by R¹, R², R³, R⁴, R⁵, and R⁶ in the above formulas (i), (ii), (iii), and (iv), and divalent groups obtained by further removing one hydrogen atom from those monovalent organic groups. Among them, the k-valent organic group having 1 to 20 carbon atoms represented by Y is preferably a group obtained by removing k hydrogen atoms from a group containing an aromatic hydrocarbon ring having 6 to 20 ring members, and more preferably a group obtained by removing k hydrogen atoms from a group containing a benzene ring, a naphthalene ring, an anthracene ring, a pyrene ring, a fluorene ring, or a perylene ring. In addition, from the viewpoint of improving resistance to basic hydrogen peroxide water such as a mixed washing liquid (SC-1) composed of ammonia water, hydrogen peroxide water, and ultrapure water, a structure in which these rings are combined with a group having an acetal structure, more specifically, a 1,3-benzodioxol structure is also preferable.

Examples of the compound [A] represented by formula (2-1) include compounds represented by formulas (2-1-1) to (2-1-7) (hereinafter also referred to as “compounds (2-1-1) to (2-1-7)”).

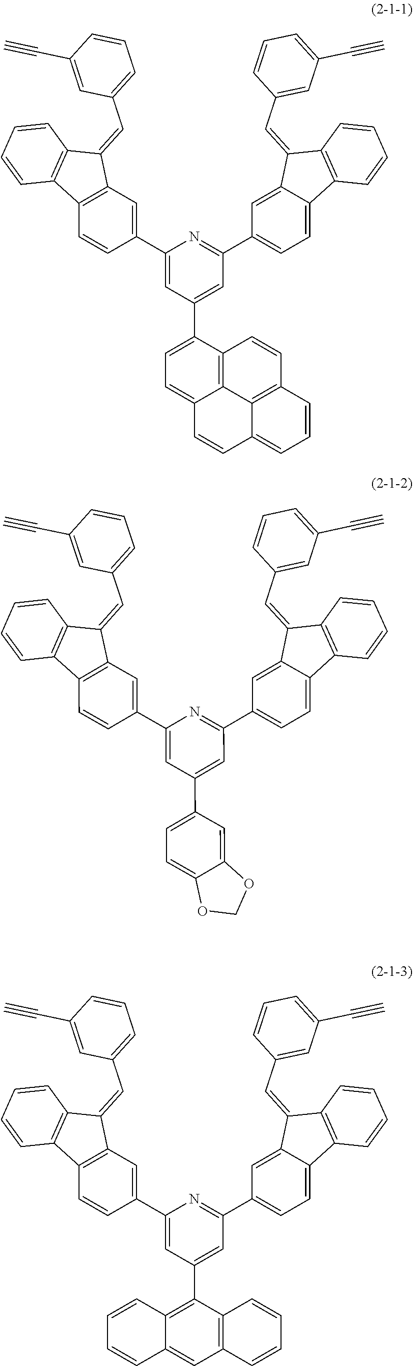 [SMILES: C#Cc1cccc(/C=C2\c3ccccc3-c3ccc(-c4cc(-c5ccc6ccc7cccc8ccc5c6c78)cc(-c5ccc6c(c5)/C(=C/c5cccc(C#C)c5)c5ccccc5-6)n4)cc32)c1 ; C#Cc1cccc(/C=C2\c3ccccc3-c3ccc(-c4cc(-c5ccc6c(c5)OCO6)cc(-c5ccc6c(c5)/C(=C/c5cccc(C#C)c5)c5ccccc5-6)n4)cc32)c1 ; C#Cc1cccc(/C=C2\c3ccccc3-c3ccc(-c4cc(-c5c6ccccc6cc6ccccc56)cc(-c5ccc6c(c5)/C(=C/c5cccc(C#C)c5)c5ccccc5-6)n4)cc32)c1]

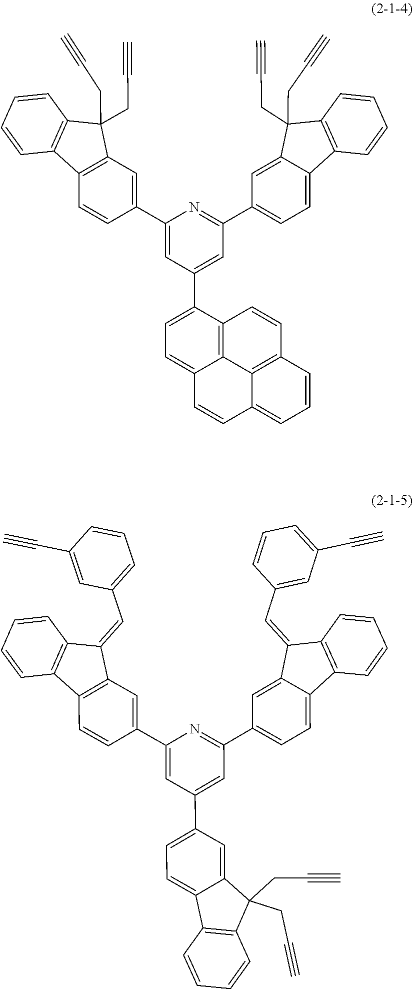 [SMILES: C#CCC1(CC#C)c2ccccc2-c2ccc(-c3cc(-c4ccc5ccc6cccc7ccc4c5c67)cc(-c4ccc5c(c4)C(CC#C)(CC#C)c4ccccc4-5)n3)cc21 ; C#CCC1(CC#C)c2ccccc2-c2ccc(-c3cc(-c4ccc5c(c4)/C(=C/c4cccc(C#C)c4)c4ccccc4-5)nc(-c4ccc5c(c4)/C(=C/c4cccc(C#C)c4)c4ccccc4-5)c3)cc21]

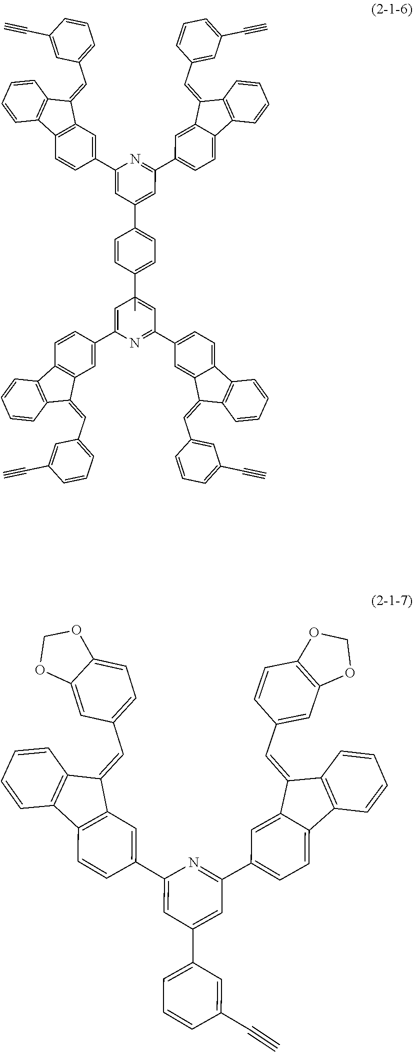

Examples of the compound [A] represented by formula (2-2) include compounds represented by formulas (2-2-1) to (2-2-6) (hereinafter also referred to as “compounds (2-2-1) to (2-2-6)”).

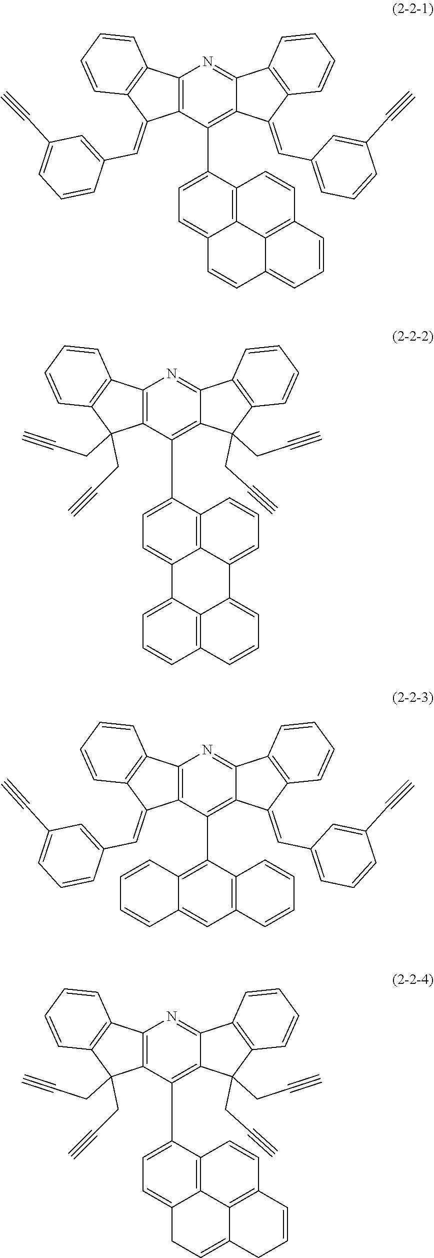

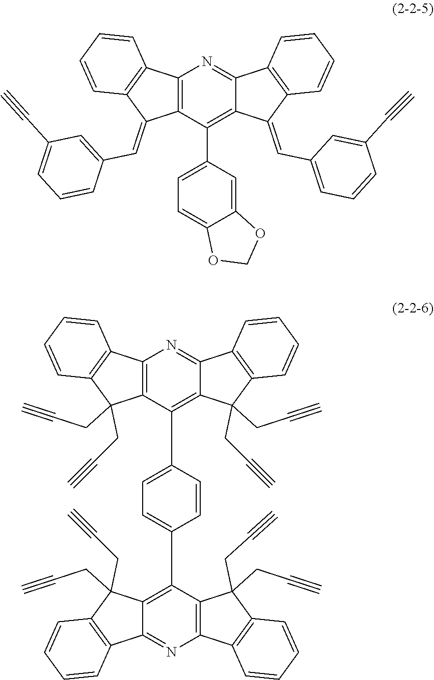

Examples of the compound [A] represented by formula (2-3) include compounds represented by formulas (2-3-1) to (2-3-6) (hereinafter also referred to as “compounds (2-3-1) to (2-3-6)”).

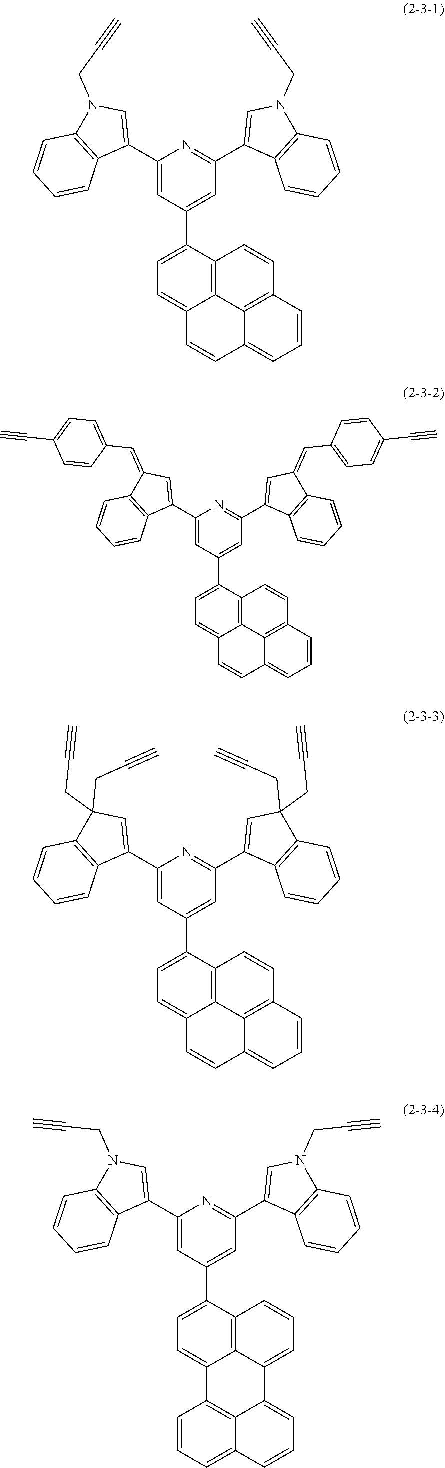

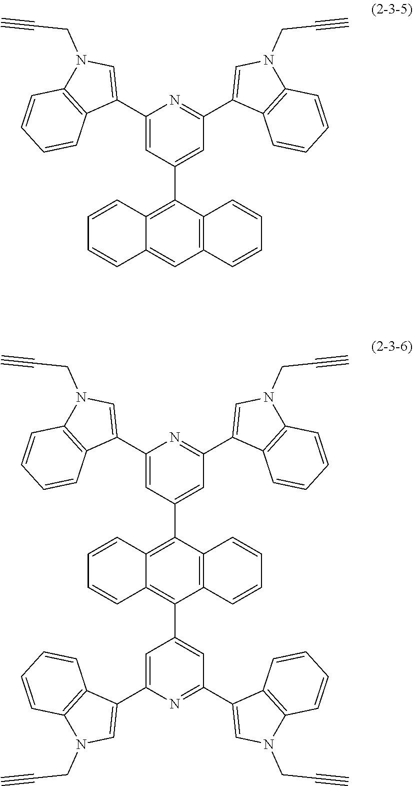

Examples of the compound [A] containing a pyridine ring structure other than the structures represented by formulas (2-1), (2-2) and (2-3) include structures represented by formulas (Z-1-1) to (Z-1-5).

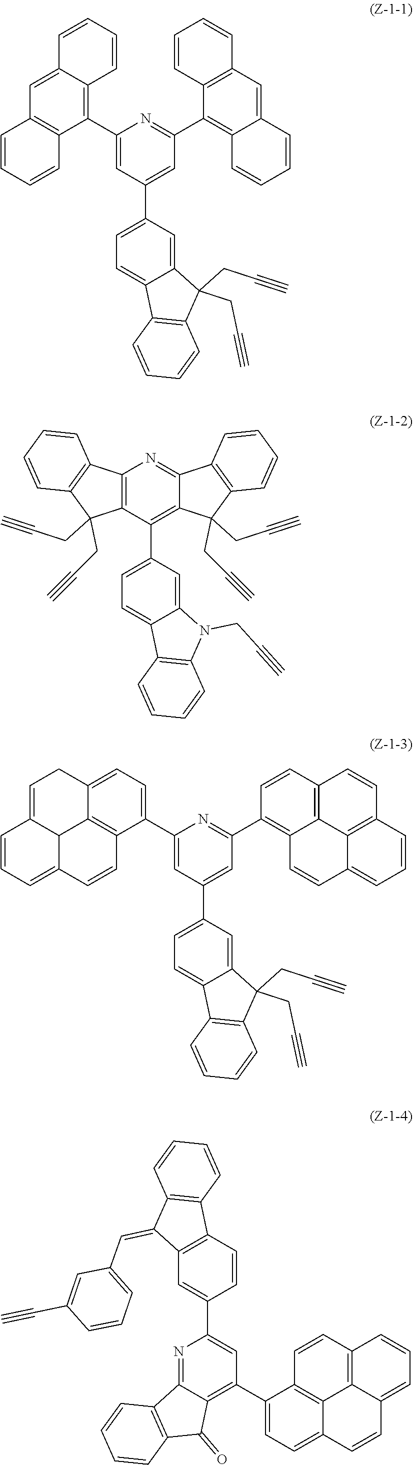

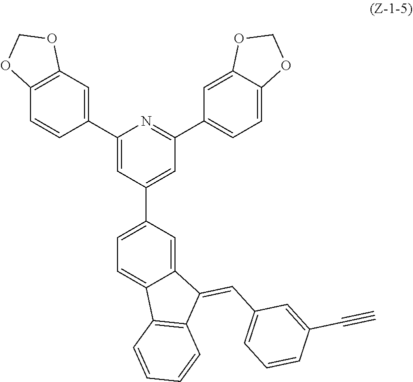 [SMILES: C#Cc1cccc(/C=C2\c3ccccc3-c3ccc(-c4cc(-c5ccc6c(c5)OCO6)nc(-c5ccc6c(c5)OCO6)c4)cc32)c1]

Examples of the compound [A] containing a pyrimidine ring structure include compounds represented by formulas (Z-2-1) to (Z-2-6).

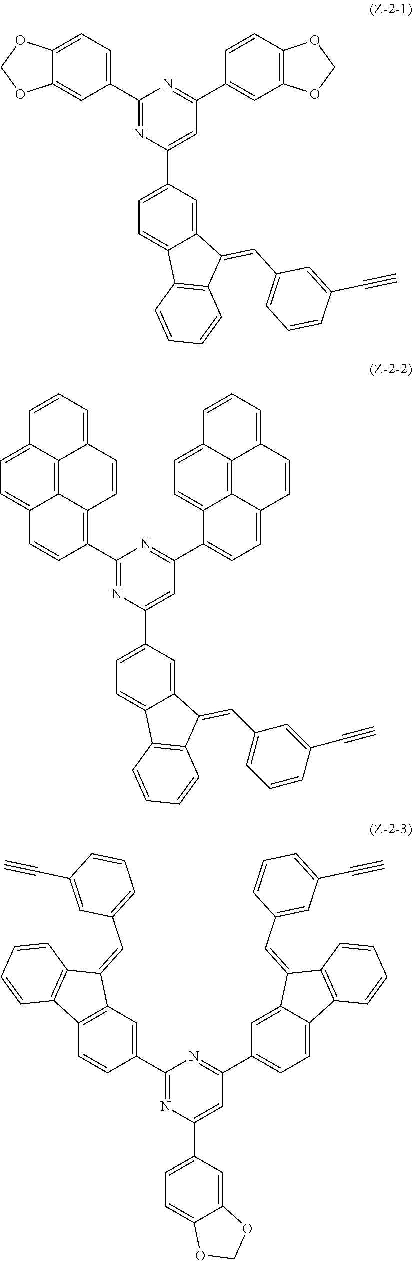 [SMILES: C#Cc1cccc(/C=C2\c3ccccc3-c3ccc(-c4cc(-c5ccc6c(c5)OCO6)nc(-c5ccc6c(c5)OCO6)n4)cc32)c1 ; C#Cc1cccc(/C=C2\c3ccccc3-c3ccc(-c4cc(-c5ccc6ccc7cccc8ccc5c6c78)nc(-c5ccc6ccc7cccc8ccc5c6c78)n4)cc32)c1 ; C#Cc1cccc(/C=C2\c3ccccc3-c3ccc(-c4cc(-c5ccc6c(c5)OCO6)nc(-c5ccc6c(c5)/C(=C/c5cccc(C#C)c5)c5ccccc5-6)n4)cc32)c1]

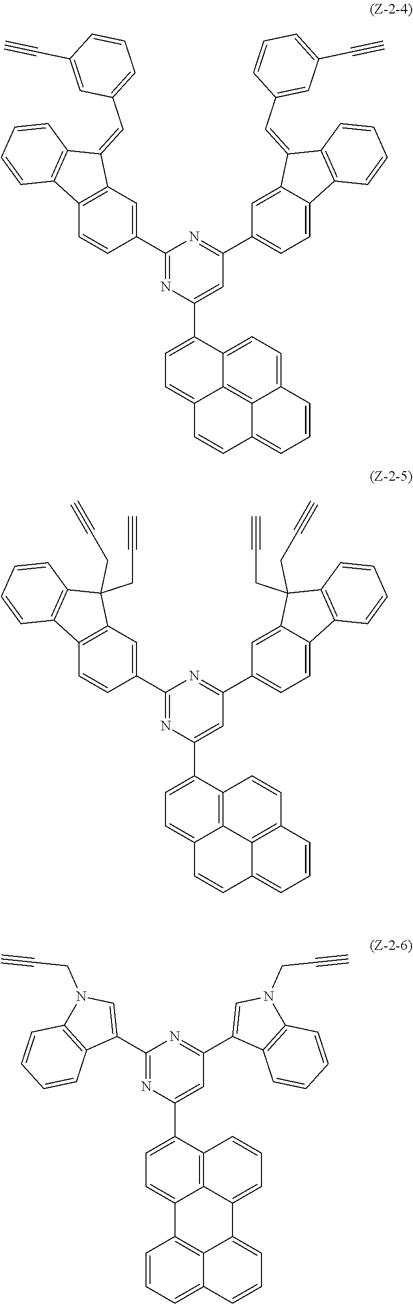 [SMILES: C#Cc1cccc(/C=C2\c3ccccc3-c3ccc(-c4cc(-c5ccc6ccc7cccc8ccc5c6c78)nc(-c5ccc6c(c5)/C(=C/c5cccc(C#C)c5)c5ccccc5-6)n4)cc32)c1 ; C#CCC1(CC#C)c2ccccc2-c2ccc(-c3cc(-c4ccc5ccc6cccc7ccc4c5c67)nc(-c4ccc5c(c4)C(CC#C)(CC#C)c4ccccc4-5)n3)cc21 ; C#CCn1cc(-c2cc(-c3ccc4c5cccc6cccc(c7cccc3c74)c65)nc(-c3cn(CC#C)c4ccccc34)n2)c2ccccc21]

The upper limit of the molecular weight of the compound [A] is preferably 400, more preferably 500, still more preferably 550, and particularly preferably 600. The upper limit of the molecular weight is preferably 3,000, more preferably 1,500, and still more preferably 1,000. By setting the molecular weight of the compound [A] within the above range, the flatness of a resist underlayer film to be formed of the composition for forming a resist underlayer film can be further improved.

The upper limit of the content ratio of hydrogen atoms to all atoms constituting the compound [A] is preferably 5.5% by mass, more preferably 5.2% by mass, still more preferably 5.0% by mass, and particularly preferably 4.8% by mass. The lower limit of the content ratio is, for example, 0.1% by mass. By setting the content ratio of hydrogen atoms to all atoms constituting the compound [A] within the above range, the bending resistance of a resist underlayer film formed of the composition for forming a resist underlayer film can be further improved. The content ratio of hydrogen atoms to all atoms constituting the compound [A] is a value calculated from the molecular formula of the compound [A].

The lower limit of the content ratio of the compound [A] is preferably 50% by mass, more preferably 60% by mass, and still more preferably 70% by mass based on all components excluding the solvent [B] contained in the composition for forming a resist underlayer film. The upper limit of the content ratio is preferably 100% by mass, and may be 99% by mass, and also may be 98% by mass.

The lower limit of the content ratio of the compound [A] in the composition for forming a resist underlayer film is preferably 2% by mass, more preferably 4% by mass, still more preferably 5% by mass, and particularly preferably 6% by mass based on the total mass of the compound [A] and the solvent [B]. The upper limit of the content ratio is preferably 30% by mass, more preferably 25% by mass, still more preferably 20% by mass, and particularly preferably 18% by mass based on the total mass of the compound [A] and the solvent [B].

[Method for synthesizing compound [A]] A method for synthesizing the compound [A] will be described with reference to, as an example, a structure in which the compound [A] is represented by formula (2-1), X in the formula (2-1) is represented by formula (ii), and the moiety of the formula (ii) has a group represented by formula (X-1). Typically, as shown in the following scheme, a substituted pyridine ring is formed by a Krönke type pyridine synthesis method using an aldehyde, a ketone, and a nitrogen source (an amine or an ammonium salt), and the compound [A] can be synthesized through Knoevenagel condensation of a fluorene moiety and an ethynyl group-containing aldehyde under basic conditions.

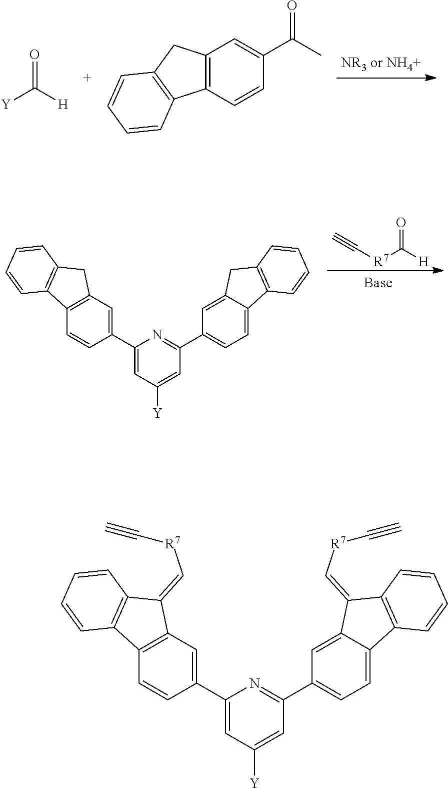

In the above scheme, Y has the same meaning as in the above formula (2-1). Each R is a hydrogen atom or a monovalent organic group having 1 to 10 carbon atoms. R⁷ has the same meaning as in the above formula (X-1). Other structures can be appropriately synthesized by changing the structure of Y of the aldehyde as a starting material, the structure of the fluorene moiety of the ketone, the structure of the ethynyl group-containing aldehyde for modification, and the like.

### <Solvent [B]>

The solvent [B] is not particularly limited as long as it can dissolve or disperse the compound [A] and optional components contained as necessary.

Examples of the solvent [B] include a hydrocarbon-based solvent, an ester-based solvent, an alcohol-based solvent, a ketone-based solvent, an ether-based solvent, and a nitrogen-containing solvent. The solvent [B] may be used singly or two or more kinds thereof may be used in combination.

Examples of the hydrocarbon-based solvent include aliphatic hydrocarbon-based solvents such as n-pentane, n-hexane, and cyclohexane, and aromatic hydrocarbon-based solvents such as benzene, toluene, and xylene.

Examples of the ester-based solvent include carbonate-based solvents such as diethyl carbonate, acetic acid monoacetate ester-based solvents such as methyl acetate and ethyl acetate, lactone-based solvents such as γ-butyrolactone, polyhydric alcohol partial ether carboxylate-based solvents such as diethylene glycol monomethyl ether acetate and propylene glycol monomethyl ether acetate, and lactate ester-based solvents such as methyl lactate and ethyl lactate.

Examples of the alcohol-based solvent include monoalcohol-based solvents such as methanol, ethanol, and n-propanol, and polyhydric alcohol-based solvents such as ethylene glycol and 1,2-propylene glycol.

Examples of the ketone-based solvent include chain ketone-based solvents such as methyl ethyl ketone and methyl isobutyl ketone, and cyclic ketone-based solvents such as cyclohexanone.

Examples of the ether-based solvent include chain ether-based solvents such as n-butyl ether, cyclic ether-based solvents such as tetrahydrofuran, polyhydric alcohol ether-based solvents such as propylene glycol dimethyl ether, and polyhydric alcohol partial ether-based solvents such as diethylene glycol monomethyl ether.

Examples of the nitrogen-containing solvent include chain nitrogen-containing solvents such as N,N-dimethylacetamide, and cyclic nitrogen-containing solvents such as N-methylpyrrolidone.

As the solvent [B], an ester-based solvent or a ketone-based solvent is preferable, a polyhydric alcohol partial ether carboxylate-based solvent or a cyclic ketone-based solvent is more preferable, and propylene glycol monomethyl ether acetate or cyclohexanone is still more preferable.

The lower limit of the content ratio of the solvent [B] in the composition for forming a resist underlayer film is preferably 50% by mass, more preferably 60% by mass, and still more preferably 70% by mass. The upper limit of the content ratio is preferably 99.9% by mass, more preferably 99% by mass, and still more preferably 95% by mass.

### (Optional Component)

The composition for forming a resist underlayer film may include an optional component as long as the effect of the composition is not impaired. Examples of the optional component include an acid generator, a crosslinking agent, and a surfactant. The optional component may be used singly or two or more kinds thereof may be used in combination. The content ratio of the optional component in the composition for forming a resist underlayer film can be appropriately determined according to the type and the like of the optional component.

### [Method for Preparing Composition for Forming Resist Underlayer Film]

The composition for forming a resist underlayer film can be prepared by mixing the compound [A], the solvent [B] and, as necessary, an optional component in a prescribed ratio and preferably filtering the resulting mixture through a membrane filter having a pore size of 0.02 μm to 0.5 μm or the like.

### [Applying Step]

In this step, a composition for forming a resist underlayer film is applied directly or indirectly to a substrate. The method of the application of the composition for forming a resist underlayer film is not particularly limited, and the application can be performed by an appropriate method such as spin coating, cast coating, or roll coating. As a result, a coating film is formed, and volatilization of the solvent [B] or the like occurs, so that a resist underlayer film is formed.

Examples of the substrate include metallic or semimetallic substrates such as a silicon substrate, an aluminum substrate, a nickel substrate, a chromium substrate, a molybdenum substrate, a tungsten substrate, a copper substrate, a tantalum substrate, and a titanium substrate. Among them, a silicon substrate is preferred. The substrate may be a substrate having a silicon nitride film, an alumina film, a silicon dioxide film, a tantalum nitride film, or a titanium nitride film formed thereon.

Examples of the case where the composition for forming a resist underlayer film is applied indirectly to the substrate include a case where the composition for forming a resist underlayer film is applied to a silicon-containing film described later formed on the substrate.

### [Heating Step]

In this step, before a resist pattern is formed, the resist underlayer film is heated at 250° C. or higher. The formation of the resist underlayer film is promoted by heating the coating film. More specifically, volatilization or the like of the solvent [B] is promoted by heating the coating film.

The heating of the coating film may be performed either in the air atmosphere or in a nitrogen atmosphere. The lower limit of the heating temperature is preferably 250° C., more preferably 260° C., and still more preferably 280° C. The upper limit of the heating temperature is preferably 600° C., and more preferably 500° C. The lower limit of the heating time is preferably 15 seconds, and more preferably 30 seconds. The upper limit of the time is preferably 1,200 seconds, and more preferably 600 seconds.

After the applying step, the resist underlayer film may be subjected to exposure. After the applying step, the resist underlayer film may be exposed to plasma. After the applying step, the resist underlayer film may be ion-implanted. When the resist underlayer film is exposed, the etching resistance of the resist underlayer film is improved. When the resist underlayer film is exposed to plasma, the etching resistance of the resist underlayer film is improved. When the resist underlayer film is subjected to ion implantation, the etching resistance of the resist underlayer film is improved.

The radiation to be used for exposure of the resist underlayer film is appropriately selected from among electromagnetic waves such as visible rays, ultraviolet rays, far ultraviolet rays, X-rays, and γ-rays and corpuscular rays such as electron beam, molecular beams, and ion beams.

Examples of the method for exposing the resist underlayer film to plasma include a direct method in which a substrate is placed in each gas atmosphere and plasma discharge is performed. As plasma exposure conditions, usually, the gas flow rate is 50 cc/min or more and 100 cc/min or less, and the supply power is 100 W or more and 1,500 W or less.

The lower limit of the time of the exposure to plasma is preferably 10 seconds, more preferably 30 seconds, and still more preferably 1 minute. The upper limit of the time is preferably 10 minutes, more preferably 5 minutes, and still more preferably 2 minutes.

The plasma is generated, for example, under an atmosphere of a mixed gas of H₂ gas and Ar gas. In addition to the H₂ gas and the Ar gas, a carbon-containing gas such as a CF₄ gas or a CH₄ gas may be introduced. At least one among a CF₄ gas, an NF₃ gas, a CHF₃ gas, a CO₂ gas, a CH₂F₂ gas, a CH₄ gas, and a C₄F₈ gas may be introduced instead of one or both of the H₂ gas and the Ar gas.

In the ion implantation into the resist underlayer film, a dopant is implanted into the resist underlayer film. The dopant may be selected from the group consisting of boron, carbon, nitrogen, phosphorus, arsenic, aluminum, and tungsten. The implantation energy utilized to apply a voltage to the dopant may be from about 0.5 keV to 60 keV depending on the type of the dopant to be utilized and a desired depth of implantation.

The lower limit of the average thickness of the resist underlayer film to be formed is preferably 10 nm, more preferably 20 nm, and still more preferably 30 nm. The upper limit of the average thickness is preferably 3,000 nm, more preferably 1,000 nm, and still more preferably 100 nm. The average thickness is measured as described in Examples.

### [Silicon-Containing Film Forming Step]

In this step, before a resist pattern is formed, a silicon-containing film is formed directly or indirectly on the resist underlayer film formed through the applying step and, as necessary, the heating step. Examples of the case where the silicon-containing film is formed indirectly on the resist underlayer film include a case where a surface modification film of the resist underlayer film is formed on the resist underlayer film. The surface modification film of the resist underlayer film is, for example, a film having a contact angle with water different from that of the resist underlayer film.

The silicon-containing film can be formed by, for example, application, chemical vapor deposition (CVD), atomic layer deposition (ALD), or the like of a composition for forming a silicon-containing film. Examples of a method for forming a silicon-containing film by application of a composition for forming a silicon-containing film include a method in which a coating film formed by applying a composition for forming a silicon-containing film directly or indirectly to the resist underlayer film is cured by exposure and/or heating. As a commercially available product of the composition for forming a silicon-containing film, for example, “NFC SOG01”, “NFC SOG04”, or “NFC SOG080” (all manufactured by JSR Corporation) can be used. By chemical vapor deposition (CVD) or atomic layer deposition (ALD), a silicon oxide film, a silicon nitride film, a silicon oxynitride film, or an amorphous silicon film can be formed.

Examples of the radiation to be used for the exposure include electromagnetic waves such as visible rays, ultraviolet rays, far ultraviolet rays, X-rays, and γ-rays and corpuscular rays such as electron beam, molecular beams, and ion beams.

The lower limit of the temperature in heating the coating film is preferably 90° C., more preferably 150° C., and still more preferably 200° C. The upper limit of the temperature is preferably 550° C., more preferably 450° C., and still more preferably 300° C.

The lower limit of the average thickness of the silicon-containing film is preferably 1 nm, more preferably 10 nm, and still more preferably 20 nm. The upper limit is preferably 20,000 nm, more preferably 1,000 nm, and still more preferably 100 nm. The average thickness of the silicon-containing film is a value measured using the spectroscopic ellipsometer in the same manner as for the average thickness of the resist underlayer film.

### [Resist Pattern Forming Step]

In this step, a resist pattern is formed directly or indirectly on the resist underlayer film. Examples of a method for performing this step include a method using a resist composition, a method using nanoimprinting, and a method using a self-assembly composition. Examples of the case of forming a resist pattern indirectly on the resist underlayer film include a case of forming a resist pattern on the silicon-containing film.

Examples of the resist composition include a positive or negative chemically amplified resist composition containing a radiation sensitive acid generator, a positive resist composition containing an alkali-soluble resin and a quinonediazide-based photosensitizer, and a negative resist composition containing an alkali-soluble resin and a crosslinking agent.

First, a resist composition is applied directly or indirectly to the resist underlayer film to form a resist film. Examples of the method of applying the resist composition include a spin coating method. After the application, prebaking (PB) may be performed to promote the volatilization of the solvent contained in the coating film, as necessary. The temperature and time of the prebaking may be appropriately adjusted according to the type or the like of the resist composition to be used.

Then, the formed resist film is subjected to exposure by selective irradiation with radiation. Radiation to be used for the exposure can be appropriately selected according to the type or the like of the radiation-sensitive acid generator to be used in the resist composition, and examples thereof include electromagnetic rays such as visible rays, ultraviolet rays, far-ultraviolet, X-rays, and γ-rays and corpuscular rays such as electron beam, molecular beams, and ion beams. Among these, far-ultraviolet rays are preferable, and KrF excimer laser light (wavelength: 248 nm), ArF excimer laser light (wavelength: 193 nm), F₂ excimer laser light (wavelength: 157 nm), Kr₂ excimer laser light (wavelength: 147 nm), ArKr excimer laser light (wavelength: 134 nm) or extreme ultraviolet rays (wavelength: 13.5 nm, etc., also referred to as “EUV”) are more preferred, and ArF excimer laser light or EUV is even more preferred.

After the exposure, post-baking may be performed to improve resolution, pattern profile, developability, etc. The temperature and time of the post-baking may be appropriately determined according to the type or the like of the resist composition to be used.

Then, the exposed resist film is developed with a developer to form a resist pattern. This development may be either alkaline development or organic solvent development. Examples of the developer for alkaline development include basic aqueous solutions of ammonia, triethanolamine, tetramethylammonium hydroxide (TMAH), and tetraethylammonium hydroxide. To these basic aqueous solutions, for example, a water-soluble organic solvent such as an alcohol, e.g., methanol or ethanol, or a surfactant may be added in an appropriate amount. Examples of the developer for organic solvent development include the various organic solvents recited as examples of the solvent [B] in the composition for forming a resist underlayer film described above.

After the development with a developer, a prescribed resist pattern is formed through washing and drying.

### [Etching Step]

In this step, etching is performed using the resist pattern as a mask. The number of times of the etching may be once. Alternatively, etching may be performed a plurality of times, that is, etching may be sequentially performed using a pattern obtained by etching as a mask. From the viewpoint of obtaining a pattern having a favorable shape, etching is preferably performed a plurality of times. When performed a plurality of times, etching is performed to the silicon-containing film, the resist underlayer film, and the substrate sequentially in order. Examples of an etching method include dry etching and wet etching. Dry etching is preferable from the viewpoint of achieving a favorable shape of the pattern of the substrate. In the dry etching, for example, gas plasma such as oxygen plasma is used. As a result of the etching, a semiconductor substrate having a prescribed pattern is obtained.

The dry etching can be performed using, for example, a publicly known dry etching apparatus. The etching gas used for dry etching can be appropriately selected according to the elemental composition of the film to be etched, and for example, fluorine-based gases such as CHF₃, CF₄, C₂F₆, C₃F₈, and SF₆, chlorine-based gases such as Cl₂ and BCl₃, oxygen-based gases such as O₂, O₃, and H₂O, reducing gases such as H₂, NH₃, CO, CO₂, CH₄, C₂H₂, C₂H₄, C₂H₆, C₃H₄, C₃H₆, C₃H₈, HF, HI, HBr, HCl, NO, and BCl₃, and inert gases such as He, N₂ and Ar are used. These gases can also be mixed and used. When the resist underlayer film is etched, an oxygen-based gas is usually used. When the substrate is etched using the pattern of the resist underlayer film as a mask, a fluorine-based gas is usually used.

### <<Composition>>

The composition includes a compound containing at least one nitrogen-containing ring structure selected from the group consisting of a pyridine ring structure and a pyrimidine ring structure and a partial structure represented by formula (1-1) or (1-2), and a solvent.

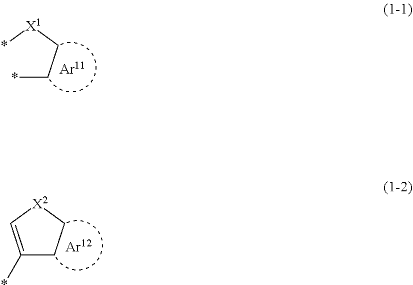

in the formulas (1-1) and (1-2), X¹ and X² are each independently a group represented by formula (i), (ii), (iii) or (iv); * is a bond with a moiety of the compound other than the partial structure represented by formula (1-1) or (1-2); and Ar¹¹ and Ar¹² are each independently a substituted or unsubstituted aromatic ring having 5 to 20 ring members that forms a fused ring structure together with two adjacent carbon atoms in the formulas (1-1) and (1-2),

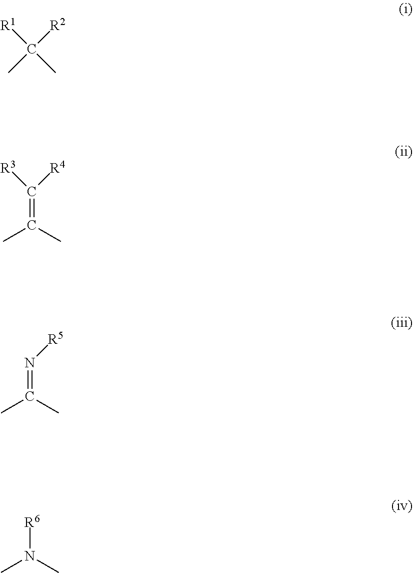

in the formula (i), R¹ and R² are each independently a hydrogen atom or a monovalent organic group having 1 to 20 carbon atoms;

in the formula (ii), R³ and R⁴ are each independently a hydrogen atom or a monovalent organic group having 1 to 20 carbon atoms;

in the formula (iii), R⁵ is a monovalent organic group having 1 to 20 carbon atoms; and in the formula (iv), R⁶ is a hydrogen atom or a monovalent organic group having 1 to 20 carbon atoms.

The compound described above in this composition corresponds to the compound [A] in the composition for forming a resist underlayer film described above, and the solvent corresponds to the solvent [B]. Therefore, the composition for forming a resist underlayer film described above can be suitably used as this composition except for the use for resist underlayer film formation.

This composition is suitably used for forming a resist underlayer film, but is not limited thereto, and can be applied to other interlayer films, surface modification films, sealing films, and the like.

### EXAMPLES

Hereinbelow, the present disclosure will specifically be described on the basis of examples, but is not limited to these examples.

### [Weight-Average Molecular Weight (Mw)]

The Mw of a polymer (x-1) was measured by gel permeation chromatography (detector: differential refractometer) with monodisperse polystyrene standards using GPC columns (“G2000HXL”×2 and “G3000HXL”×1) manufactured by Tosoh Corporation under the following analysis conditions: flow rate: 1.0 mL/min; elution solvent: tetrahydrofuran; column temperature: 40° C.

### [Average Thickness of Film]

The average thickness of a film was determined as a value obtained by measuring the film thickness at arbitrary nine points at intervals of 5 cm including the center of the resist underlayer film using a spectroscopic ellipsometer (“M2000D” available from J. A. WOOLLAM Co.) and calculating the average value of the film thicknesses.

### <Synthesis of Compound [A]>

Compounds represented by formulas (A-1) to (A-10) (hereinafter also referred to as “compounds (A-1) to (A-10)”), a polymer represented by formula (X-1) (hereinafter also referred to as “polymer (X-1)”), and a compound represented by formula (X-2) (hereinafter also referred to as “compound (X-2)”) were synthesized by the procedures described below.

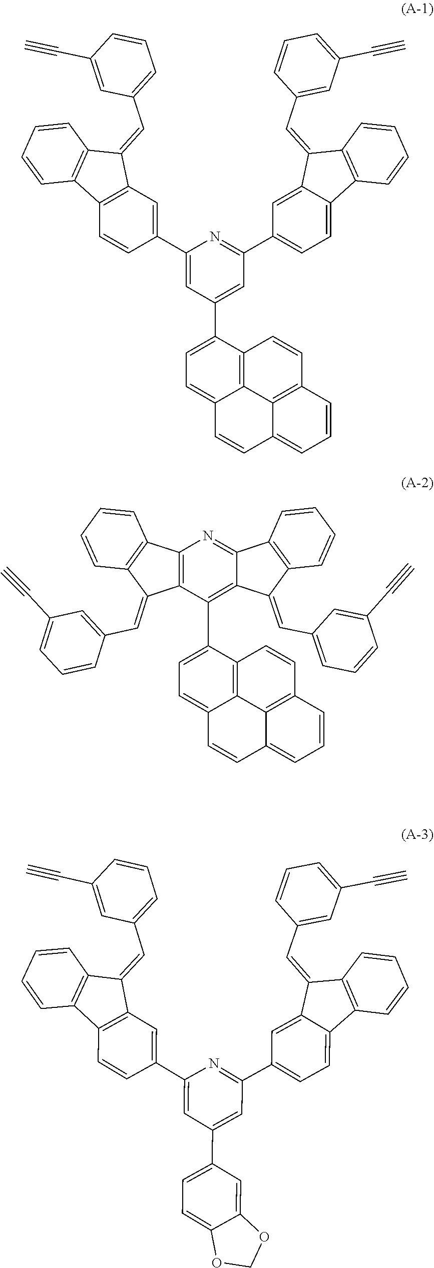 [SMILES: C#Cc1cccc(/C=C2\c3ccccc3-c3ccc(-c4cc(-c5ccc6ccc7cccc8ccc5c6c78)cc(-c5ccc6c(c5)/C(=C/c5cccc(C#C)c5)c5ccccc5-6)n4)cc32)c1 ; C#Cc1cccc(/C=C2\c3ccccc3-c3nc4c(c(-c5ccc6ccc7cccc8ccc5c6c78)c32)/C(=C/c2cccc(C#C)c2)c2ccccc2-4)c1 ; C#Cc1cccc(/C=C2\c3ccccc3-c3ccc(-c4cc(-c5ccc6c(c5)OCO6)cc(-c5ccc6c(c5)/C(=C/c5cccc(C#C)c5)c5ccccc5-6)n4)cc32)c1]

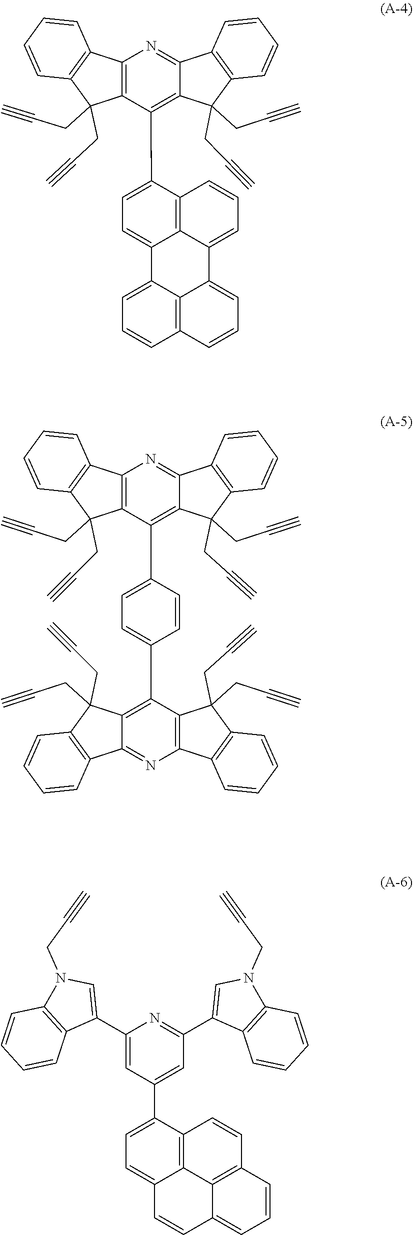

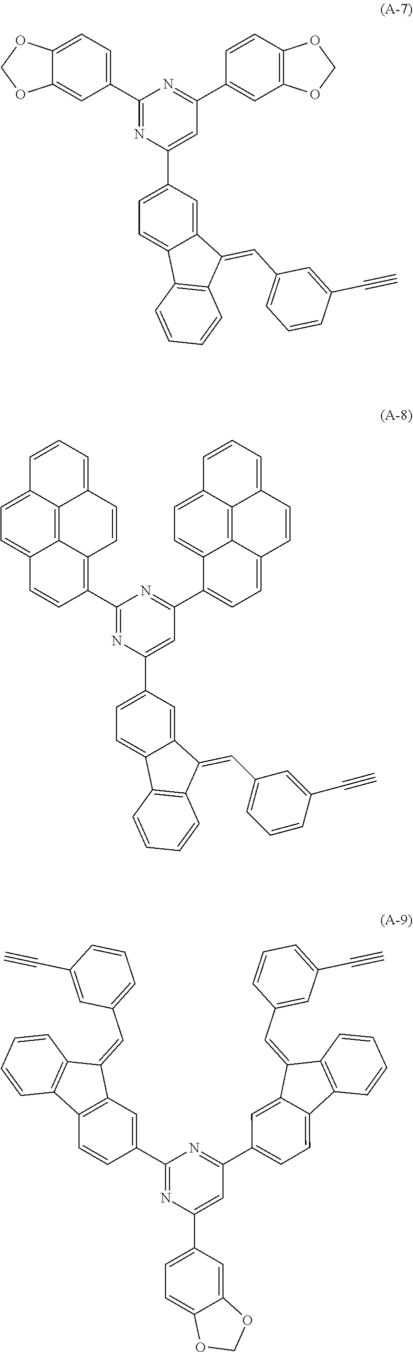 [SMILES: C#Cc1cccc(/C=C2\c3ccccc3-c3ccc(-c4cc(-c5ccc6c(c5)OCO6)nc(-c5ccc6c(c5)OCO6)n4)cc32)c1 ; C#Cc1cccc(/C=C2\c3ccccc3-c3ccc(-c4cc(-c5ccc6ccc7cccc8ccc5c6c78)nc(-c5ccc6ccc7cccc8ccc5c6c78)n4)cc32)c1 ; C#Cc1cccc(/C=C2\c3ccccc3-c3ccc(-c4cc(-c5ccc6c(c5)OCO6)nc(-c5ccc6c(c5)/C(=C/c5cccc(C#C)c5)c5ccccc5-6)n4)cc32)c1]

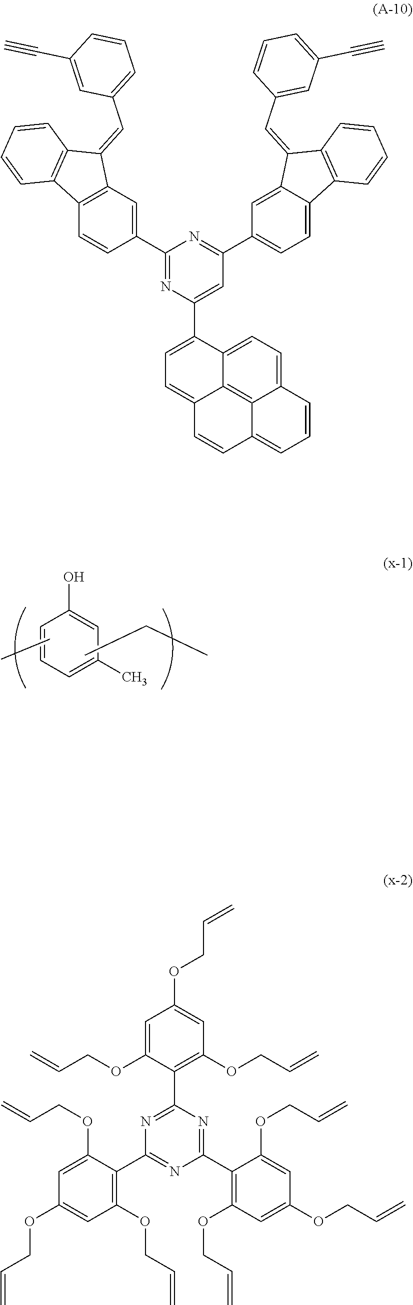

### [Synthesis Example 1] (Synthesis of Compound (a-1))

In a nitrogen atmosphere, 30.0 g of 2-acetylfluorene, 16.6 g of 1-formylpyrene, 9.26 g of benzylamine, and 28.0 g of decalin were charged into a reaction vessel, and the mixture was heated to 80° C. to be dissolved. Then, 0.69 g of diphenylammonium trifluoromethanesulfonate was added, and then the mixture was heated to 130° C. and reacted for 20 hours. After completion of the reaction, 90 g of toluene, 60 g of water, and 180 g of hexane were added, affording a precipitate. The resulting precipitate was collected with a filter paper, washed with a 50/50 wt % solution of tetrahydrofuran/hexane, and dried, affording compound (a-1) represented by formula (a-1).

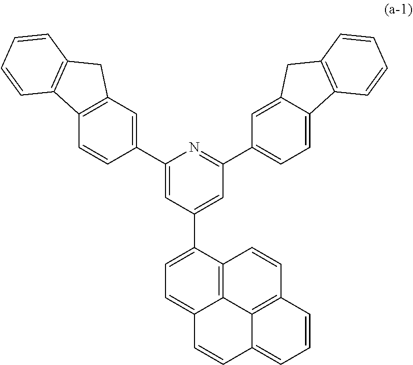 [SMILES: c1ccc2c(c1)Cc1cc(-c3cc(-c4ccc5ccc6cccc7ccc4c5c67)cc(-c4ccc5c(c4)Cc4ccccc4-5)n3)ccc1-2]

### [Synthesis Example 2] (Synthesis of Compound (a-2))

In a nitrogen atmosphere, 30.0 g of indanone, 26.1 g of 1-formylpyrene, 13.5 g of ammonium acetate, and 281 g of ethanol were charged into a reaction vessel, and the mixture was heated to 70° C. to be dissolved. Then, 1.96 g of L-prolin was added, and then the mixture was heated to 85° C. and reacted for 18 hours. After completion of the reaction, 280 g of methanol was added, affording a precipitate. The resulting precipitate was collected with a filter paper, washed with a 50/50 wt % solution of tetrahydrofuran/hexane, and dried, affording compound (a-2) represented by formula (a-2).

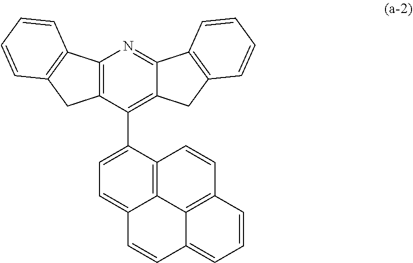 [SMILES: c1ccc2c(c1)Cc1c-2nc2c(c1-c1ccc3ccc4cccc5ccc1c3c45)Cc1ccccc1-2]

### [Synthesis Example 3] (Synthesis of Compound (a-3))

In a nitrogen atmosphere, 30.0 g of 2-acetylfluorene, 10.8 g of piperonal, 34.2 g of ammonium acetate, and 61.2 g of chlorobenzene were charged into a reaction vessel, and the mixture was heated to 100° C. to be dissolved. Then, 1.08 g of iodine was added, and then the mixture was heated to 135° C. and reacted for 18 hours. After completion of the reaction, 60 g of toluene, 60 g of water, and 120 g of hexane were added, affording a precipitate. The resulting precipitate was collected with a filter paper, washed with a 50/50 wt % solution of tetrahydrofuran/hexane, and dried, affording compound (a-3) represented by formula (a-3).

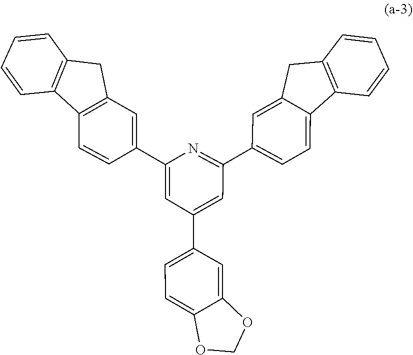 [SMILES: c1ccc2c(c1)Cc1cc(-c3cc(-c4ccc5c(c4)OCO5)cc(-c4ccc5c(c4)Cc4ccccc4-5)n3)ccc1-2]

### [Synthesis Example 4] (Synthesis of Compound (a-4))

In a nitrogen atmosphere, 15.0 g of indanone, 15.9 g of 3-formylperylene, 6.73 g of ammonium acetate, 92.8 g of dioxane, and 309 g of ethanol were charged into a reaction vessel, and the mixture was heated to 70° C. to be dissolved. Then, 1.96 g of L-prolin was added, and then the mixture was heated to 85° C. and reacted for 24 hours. After completion of the reaction, 310 g of methanol was added, affording a precipitate. The resulting precipitate was collected with a filter paper, washed with a 50/50 wt % solution of tetrahydrofuran/hexane, and dried, affording compound (a-4) represented by formula (a-4).

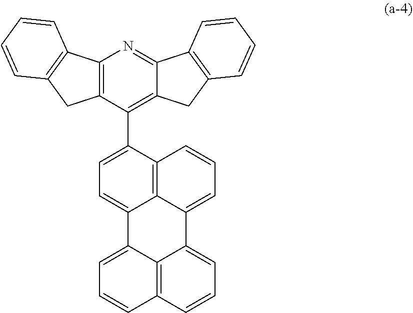 [SMILES: c1ccc2c(c1)Cc1c-2nc2c(c1-c1ccc3c4cccc5cccc(c6cccc1c63)c54)Cc1ccccc1-2]

### [Synthesis Example 5] (Synthesis of Compound (a-5))

In a nitrogen atmosphere, 30.0 g of indanone, 15.2 g of terephthalaldehyde, 26.9 g of ammonium acetate, and 226 g of ethanol were charged into a reaction vessel, and the mixture was heated to 70° C. to be dissolved. Then, 3.92 g of L-prolin was added, and then the mixture was heated to 85° C. and reacted for 24 hours. After completion of the reaction, 230 g of methanol was added, affording a precipitate. The resulting precipitate was collected with a filter paper, washed with a 50/50 wt % solution of tetrahydrofuran/hexane, and dried, affording compound (a-5) represented by formula (a-5).

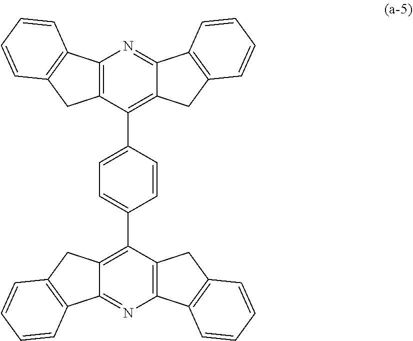 [SMILES: c1ccc2c(c1)Cc1c-2nc2c(c1-c1ccc(-c3c4c(nc5c3Cc3ccccc3-5)-c3ccccc3C4)cc1)Cc1ccccc1-2]

### [Synthesis Example 6] (Synthesis of Compound (a-6))

In a nitrogen atmosphere, 30.0 g of 3-acetylindole, 21.7 g of 1-formylpyrene, 44.7 g of ammonium acetate, and 77.5 g of chlorobenzene were charged into a reaction vessel, and the mixture was heated to 100° C. to be dissolved. Then, 1.41 g of iodine was added, and then the mixture was heated to 135° C. and reacted for 18 hours. After completion of the reaction, 60 g of toluene, 60 g of water, and 120 g of hexane were added, affording a precipitate. The resulting precipitate was collected with a filter paper, washed with a 50/50 wt % solution of tetrahydrofuran/hexane, and dried, affording compound (a-6) represented by formula (a-6).

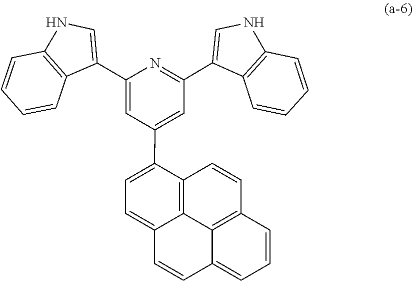 [SMILES: c1cc2ccc3ccc(-c4cc(-c5c[nH]c6ccccc56)nc(-c5c[nH]c6ccccc56)c4)c4ccc(c1)c2c34]

### [Synthesis Example 7] (Synthesis of Compound (a-7))

In a nitrogen atmosphere, 15.0 g of 2-acetylfluorene, 21.4 g of piperonal, 44.7 g of ammonium iodide, and 77.5 g of chlorobenzene were charged into a reaction vessel, and the mixture was heated to 100° C. to be dissolved. Then, 1.41 g of iodine was added, and then the mixture was heated to 135° C. and reacted for 18 hours. After completion of the reaction, 60 g of toluene, 60 g of water, and 120 g of hexane were added, affording a precipitate. The resulting precipitate was collected with a filter paper, washed with a 50/50 wt % solution of tetrahydrofuran/hexane, and dried, affording compound (a-7) represented by formula (a-7).

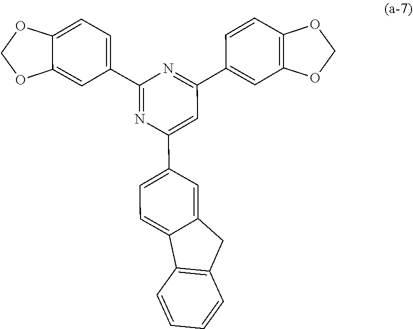 [SMILES: c1ccc2c(c1)Cc1cc(-c3cc(-c4ccc5c(c4)OCO5)nc(-c4ccc5c(c4)OCO5)n3)ccc1-2]

### [Synthesis Example 8] (Synthesis of Compound (a-8))

In a nitrogen atmosphere, 15.0 g of 2-acetylfluorene, 33.2 g of 1-formylpyrene, 20.8 g of ammonium carbonate, and 77.5 g of chlorobenzene were charged into a reaction vessel, and the mixture was heated to 100° C. to be dissolved. Then, 1.41 g of iodine was added, and then the mixture was heated to 135° C. and reacted for 18 hours. After completion of the reaction, 60 g of toluene, 60 g of water, and 120 g of hexane were added, affording a precipitate. The resulting precipitate was collected with a filter paper, washed with a 50/50 wt % solution of tetrahydrofuran/hexane, and dried, affording compound (a-8) represented by formula (a-8).

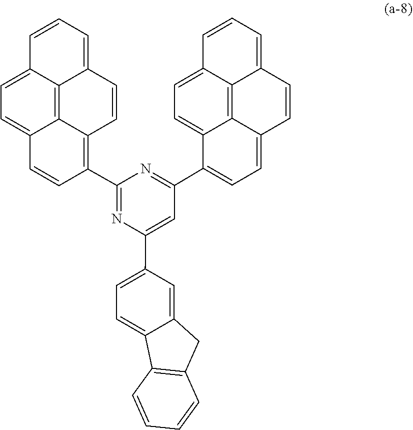 [SMILES: c1ccc2c(c1)Cc1cc(-c3cc(-c4ccc5ccc6cccc7ccc4c5c67)nc(-c4ccc5ccc6cccc7ccc4c5c67)n3)ccc1-2]

### [Synthesis Example 9] (Synthesis of Compound (a-9))

In a nitrogen atmosphere, 15.0 g of 5-acetyl-1,3-benzodioxol, 35.5 g of 2-fluorenecarboxaldehyde, 20.8 g of ammonium carbonate, and 77.5 g of chlorobenzene were charged into a reaction vessel, and the mixture was heated to 100° C. to be dissolved. Then, 1.41 g of iodine was added, and then the mixture was heated to 135° C. and reacted for 18 hours. After completion of the reaction, 60 g of toluene, 60 g of water, and 120 g of hexane were added, affording a precipitate. The resulting precipitate was collected with a filter paper, washed with a 50/50 wt % solution of tetrahydrofuran/hexane, and dried, affording compound (a-9) represented by formula (a-9).

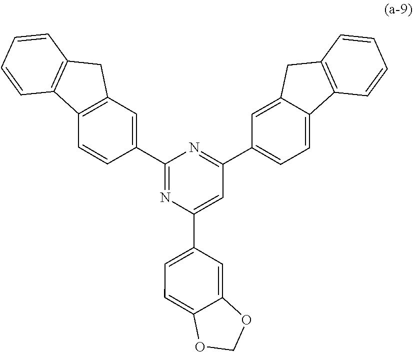 [SMILES: c1ccc2c(c1)Cc1cc(-c3cc(-c4ccc5c(c4)OCO5)nc(-c4ccc5c(c4)Cc4ccccc4-5)n3)ccc1-2]

### [Synthesis Example 10] (Synthesis of Compound (a-10))

In a nitrogen atmosphere, 15.0 g of 5-acetyl-1,3-benzodioxole, 22.3 g of acetylpyrene, 20.8 g of ammonium carbonate, and 77.5 g of chlorobenzene were charged into a reaction vessel, and the mixture was heated to 100° C. to be dissolved. Then, 1.41 g of iodine was added, and then the mixture was heated to 135° C. and reacted for 18 hours. After completion of the reaction, 60 g of toluene, 60 g of water, and 120 g of hexane were added, affording a precipitate. The resulting precipitate was collected with a filter paper, washed with a 50/50 wt % solution of tetrahydrofuran/hexane, and dried, affording compound (a-10) represented by formula (a-10).

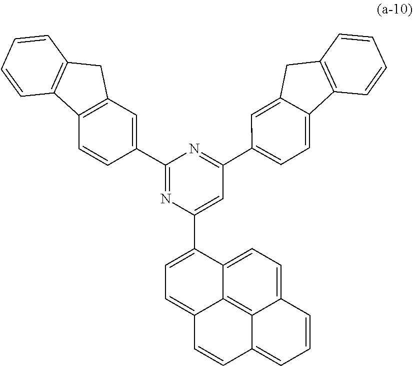 [SMILES: c1ccc2c(c1)Cc1cc(-c3cc(-c4ccc5ccc6cccc7ccc4c5c67)nc(-c4ccc5c(c4)Cc4ccccc4-5)n3)ccc1-2]

### [Synthesis Example 11] (Synthesis of Compound (A-1))

In a nitrogen atmosphere, 10.0 g of the compound (a-1), 4.5 g of m-ethynylbenzaldehyde, and 43.5 g of tetrahydrofuran were added to a reaction vessel, and the mixture was stirred. Then, 43.2 g of a 25% by mass aqueous tetramethylammonium hydroxide solution and 1.06 g of tetrabutylammonium bromide were added thereto, and the mixture was reacted at 40° C. for 4 hours. After completion of the reaction, the aqueous phase was removed, and then 45 g of a 5% by mass aqueous solution of oxalic acid and 44 g of methyl isobutyl ketone were added. After the aqueous phase was removed, liquid separation extraction with water was performed, and the organic layer was charged into hexane and reprecipitated. The precipitate was collected on a filter paper and dried, affording compound (A-1).

### [Synthesis Example 12] (Synthesis of Compound (A-2))

Compound (A-2) was obtained in the same manner as in Synthesis Example 11 except that 7.6 g of the compound (a-2) was used in place of 10.0 g of the compound (a-1).

### [Synthesis Example 13] (Synthesis of Compound (A-3))

Compound (A-3) was obtained in the same manner as in Synthesis Example 11 except that 8.8 g of the compound (a-3) was used in place of 10.0 g of the compound (a-1).

### [Synthesis Example 14] (Synthesis of Compound (A-4))

In a nitrogen atmosphere, 10.0 g of the compound (a-4), 14.1 g of provalgyl bromide, and 50 g of dioxane were added to a reaction vessel, and the mixture was stirred. Then, 17.8 g of a 50% by mass aqueous potassium hydroxide solution and 1.28 g of tetrabutylammonium bromide were added thereto, and the mixture was reacted at 95° C. for 12 hours. After completion of the reaction, the aqueous phase was removed, then 40 g of water and 100 g of hexane were added, and the precipitate was collected with a filter paper and dried, affording compound (A-4).

### [Synthesis Example 15] (Synthesis of Compound (A-5))

Compound (A-5) was obtained in the same manner as in Synthesis Example 14 except that 6.0 g of the compound (a-5) was used in place of 10.0 g of the compound (a-4).

### [Synthesis Example 16] (Synthesis of Compound (A-6))

Compound (A-6) was obtained in the same manner as in Synthesis Example 14 except that 20.0 g of the compound (a-6) was used in place of 10.0 g of the compound (a-4).

### [Synthesis Example 17] (Synthesis of Compound (A-7))

In a nitrogen atmosphere, 10.0 g of the compound (a-7), 3.2 g of m-ethynylbenzaldehyde, and 43.5 g of tetrahydrofuran were added to a reaction vessel, and the mixture was stirred. Then, 43.2 g of a 25% by mass aqueous tetramethylammonium hydroxide solution and 1.06 g of tetrabutylammonium bromide were added thereto, and the mixture was reacted at 40° C. for 4 hours. After completion of the reaction, the aqueous phase was removed, and then 45 g of a 5% by mass aqueous solution of oxalic acid and 44 g of methyl isobutyl ketone were added. After the aqueous phase was removed, liquid separation extraction with water was performed, and the organic layer was charged into hexane and reprecipitated. The precipitate was collected on a filter paper and dried, affording compound (A-7).

### [Synthesis Example 18] (Synthesis of Compound (A-8))

Compound (A-8) was obtained in the same manner as in Synthesis Example 17 except that 13.3 g of the compound (a-8) was used in place of 10.0 g of the compound (a-7).

### [Synthesis Example 19] (Synthesis of Compound (A-9))

Compound (A-9) was obtained in the same manner as in Synthesis Example 17 except that 15.6 g of the compound (a-9) was used in place of 10.0 g of the compound (a-7).

### [Synthesis Example 20] (Synthesis of Compound (A-10))

Compound (A-10) was obtained in the same manner as in Synthesis Example 17 except that 17.3 g of the compound (a-10) was used in place of 10.0 g of the compound (a-7).

### [Synthesis Example 21] (Synthesis of Polymer (x-1))

In a nitrogen atmosphere, 250.0 g of m-cresol, 125.0 g of 37% by mass formalin, and 2 g of oxalic anhydride were added to a reaction vessel, and the mixture was reacted at 100° C. for 3 hours and at 180° C. for 1 hour, and then unreacted monomers were removed under reduced pressure, affording polymer (x-1). The Mw of the polymer (x-1) obtained was 11,000.

### [Synthesis Example 22] (Synthesis of Compound (x-2))

In a nitrogen atmosphere, 23.2 g of cyanuric chloride, 50.0 g of phloroglucinol, 586 g of diethyl ether, and 146 g of 1,2-dichloroethane were added to a reaction vessel, and dissolved at room temperature. After cooling to 0° C., 52.9 g (396.5 mmol) of aluminum chloride was added to initiate a reaction. After completion of the addition, the mixture was heated to 40° C. and reacted for 12 hours. After completion of the reaction, the reaction solution was concentrated to remove diethyl ether, and then reprecipitated with a large amount of 10% hydrochloric acid. The precipitate was dissolved in 300 g of dimethylformamide and 300 g of methanol, and then reprecipitated with a large amount of 10% hydrochloric acid, and the precipitate was collected. The precipitate was dispersed in 500 g of ethanol and then neutralized with triethylamine, and the precipitate was dried, affording an intermediate compound.

In a nitrogen atmosphere, 20.0 g of the intermediate compound, 120 g of N,N-dimethylacetamide, and 60.4 g of potassium carbonate were charged into a reaction vessel. Then, the resultant was heated to 60° C., and 52.9 g of allyl bromide was added thereto, and the mixture was reacted with stirring for 18 hours. Thereafter, 40 g of methyl isobutyl ketone, 40 g of tetrahydrofuran and 240 g of water were added to the reaction solution, and a liquid separation operation was performed. Then the organic phase was charged into a large amount of hexane and the precipitated compound was filtered, affording compound (x-2).

### <Preparation of Composition>

The compounds [A], the solvents [B], the acid generators [C], and the crosslinking agents [D] used for the preparation of compositions are shown below.

### [Compound [A]]

### Examples: Compounds (A-1) to (A-10) Synthesized Above

### Comparative Examples: Polymer (x-1) and Compound (x-2) Synthesized Above

### [Solvent [B]]

B-1: Propylene glycol monomethyl ether acetate
B-2: Cyclohexanone

### [Acid Generator [C]]

C-1: Bis(4-t-butylphenyl)iodonium nonafluoro-n-butanesulfonate (the compound represented by formula (C-1))

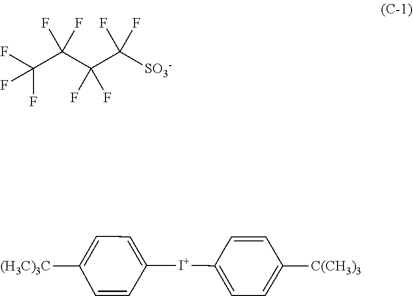

### [Crosslinking Agent [D]]

D-1: 1,3,4,6-Tetrakis(methoxymethyl)glycoluril (the compound represented by formula (D-1))

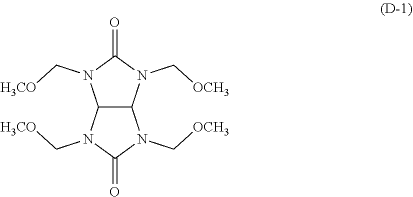 [SMILES: COCN1C(=O)N(COC)C2C1N(COC)C(=O)N2COC]

### Example 1

First, 10 parts by mass of (A-1) as the compound [A] was dissolved in 90 parts by mass of (B-1) as the solvent [B]. The resulting solution was filtered through a polytetrafluoroethylene (PTFE) membrane filter having a pore size of 0.45 μm to prepare composition (J-1).

### Examples 2 to 10 and Comparative Examples 1 to 2

Compositions (J-2) to (J-10) and (CJ-1) to (CJ-2) were prepared in the same manner as in Example 1 except that the components of the types and contents shown in the following Table 1 were used. “-” in the columns of “acid generator [C]” and “crosslinking agent [D]” in Table 1 indicates that the corresponding component was not used. The “hydrogen atom content ratio” in Table 1 indicates the content ratio of hydrogen atoms to all atoms constituting the compound [A], and is a value calculated from the molecular formula of the compound [A]. “-” in the column of “hydrogen atom content ratio” in Table 1 indicates that the hydrogen atom content ratio was not calculated.

TABLE 1

| | | Compound [A] | | | | | Acid generator | | Crosslinking | |
|---|---|---|---|---|---|---|---|---|---|---|
| | | | Hydrogen | | Solvent [B] | | [C] | | agent [D] | |
| | | | atom content | Content | | Content | | Content | | Content |
| | | | ratio | (parts by | | (parts by | | (parts by | | (parts by |
| | Composition | Type | (% by mass) | mass) | Type | mass) | Type | mass) | Type | mass) |
| Example 1 | J-1 | A-1 | 4.5 | 10 | B-2 | 90 | — | — | — | — |
| Example 2 | J-2 | A-2 | 4.3 | 10 | B-2 | 90 | — | — | — | — |
| Example 3 | J-3 | A-3 | 4.4 | 10 | B-1 | 90 | — | — | — | — |
| Example 4 | J-4 | A-4 | 4.8 | 10 | B-2 | 90 | — | — | — | — |
| Example 5 | J-5 | A-5 | 5.0 | 10 | B-2 | 90 | — | — | — | — |
| Example 6 | J-6 | A-6 | 4.7 | 10 | B-2 | 90 | — | — | — | — |
| Example 7 | J-7 | A-7 | 4.1 | 10 | B-2 | 90 | — | — | — | — |
| Example 8 | J-8 | A-8 | 4.3 | 10 | B-2 | 90 | — | — | — | — |
| Example 9 | J-9 | A-9 | 4.3 | 10 | B-3 | 90 | — | — | — | — |
| Example 10 | J-10 | A-10 | 4.4 | 10 | B-4 | 90 | — | — | — | — |
| Comparative | CJ-1 | x-1 | — | 10 | B-1 | 90 | C-1 | 0.5 | D-1 | 3 |
| Example 1 | | | | | | | | | | |
| Comparative | CJ-2 | x-2 | 6.3 | 10 | B-1 | 90 | — | — | — | — |
| Example 2 | | | | | | | | | | |

### <Evaluation>

Using the compositions obtained, etching resistance, heat resistance, and bending resistance were evaluated by the methods described below. The evaluation results are shown in the following Table 2.

### [Etching Resistance]

A composition prepared above was applied to a silicon wafer (substrate) by a spin coating method using a spin coater (“CLEAN TRACK ACT 12” available from Tokyo Electron Limited). Next, the resultant was heated at 350° C. for 60 seconds in the air atmosphere, and then cooled at 23° C. for 60 seconds to form a film having an average thickness of 200 nm, thereby affording a substrate with film, the substrate having the film formed thereon. Using an etching apparatus (“TACTRAS” manufactured by Tokyo Electron Limited), the film on the substrate with film obtained above was processed under the conditions of CF₄/Ar=110/440 sccm, PRESS.=30 MT, HF RF (high-frequency power for plasma generation)=500 W, LF RF (high-frequency power for bias)=3000 W, DCS=−150 V, RDC (gas center flow ratio)=50%, and 30 seconds, and the etching rate (nm/min) was calculated from the average thickness of the film before and after the processing. Next, the ratio with respect to Comparative Example 2 was calculated using the etching rate of Comparative Example 2 as a standard, and this ratio was taken as a measure of etching resistance. The etching resistance was evaluated as “A” (extremely good) when the ratio was 0.95 or less, “B” (good) when the ratio was more than 0.95 and less than 1.00, and “C” (poor) when the ratio was 1.00 or more. “-” in Table 2 indicates that it is an evaluation standard of etching resistance.

### [Heat Resistance]

A composition prepared above was applied to a silicon wafer (substrate) by a spin coating method using a spin coater (“CLEAN TRACK ACT 12” available from Tokyo Electron Limited). Next, the resultant was heated at 200° C. for 60 seconds in the air atmosphere, and then cooled at 23° C. for 60 seconds to form a film having an average thickness of 200 nm, thereby affording a substrate with film, the substrate having the film formed thereon. The film of the substrate with film obtained above was scraped and the resulting powder was collected. The collected powder was placed in a container to be used for measurement with a TG-DTA apparatus (“TG-DTA 2000 SR” manufactured by NETZSCH), and the mass before heating was measured. Next, the powder was heated to 400° C. at a temperature raising rate of 10° C./min in a nitrogen atmosphere using the TG-DTA apparatus, and the mass of the powder at 400° C. was measured. Then, the mass reduction rate (%) was measured from the following formula, and this mass reduction rate was taken as a measure of heat resistance.

M_{L}={(m1−m2)/m1}×100

Herein, in the above formula, M_{L} is a mass reduction rate (%), m1 is a mass (mg) before heating, and m2 is a mass (mg) at 400° C.

The smaller the mass reduction rate of the powder to be a sample, the smaller the amount of sublimate or decomposition products of the film generated during heating of the film and the better the heat resistance. That is, the smaller the mass reduction rate, the higher the heat resistance. The heat resistance was evaluated as “A” (extremely good) when the mass reduction rate was less than 5%, “B” (good) when the mass reduction rate was 5% or more and less than 10%, and “C” (poor) when the mass reduction rate was 10% or more.

### [Bending Resistance]

The composition prepared as described above was applied to a silicon substrate with a silicon dioxide film formed thereon having an average thickness of 500 nm, by a spin coating method using a spin coater (“CLEAN TRACK ACT 12” available from Tokyo Electron Limited). Next, the resultant was heated at 350° C. for 60 seconds in the air atmosphere, and then cooled at 23° C. for 60 seconds, thereby affording a substrate with film, the substrate having thereon a resist underlayer film having an average thickness of 200 nm. A composition for forming a silicon-containing film (“NFC SOG080” manufactured by JSR Corporation) was applied to the resulting substrate with film by a spin coating method, and then heated at 200° C. for 60 seconds in the air atmosphere, and further heated at 300° C. for 60 seconds, thereby forming a silicon-containing film having an average thickness of 50 nm. A resist composition for ArF (“AR1682J” manufactured by JSR Corporation) was applied to the silicon-containing film by a spin coating method, and heated (fired) at 130° C. for 60 seconds in the air atmosphere, thereby forming a resist film having an average thickness of 200 nm. The resist film was exposed with varying an exposure amount through a 1:1 line-and-space mask pattern with a target size of 100 nm using an ArF excimer laser exposure apparatus (lens numerical aperture: 0.78, exposure wavelength: 193 nm), and then heated (fired) at 130° C. for 60 seconds in the air atmosphere, developed at 25° C. for 1 minute using a 2.38% by mass aqueous tetramethylammonium hydroxide (TMAH) solution, washed with water, and dried, thereby affording a substrate on which a 200 nm-pitch line-and-space resist pattern with a line width of the line pattern of 30 nm to 100 nm was formed.

A silicon-containing film was etched using the resist pattern as a mask and using the aforementioned etching apparatus under the conditions of CF₄=200 sccm, PRESS.=85 mT, HF RF (high-frequency power for plasma generation)=500 W, LF RF (high-frequency power for bias)=0 W, DCS=−150 V, and RDC (gas center flow ratio)=50%, thereby affording a substrate on which a pattern was formed on the silicon-containing film. Subsequently, the resist underlayer film was etched using the silicon-containing film pattern as a mask and using the aforementioned etching apparatus under the conditions of O₂=400 sccm, PRESS.=25 mT, HF RF (high-frequency power for plasma generation)=400 W, LF RF (high-frequency power for bias)=0 W, DCS=0 V, and RDC (gas center flow ratio)=50%, thereby affording a substrate on which a pattern was formed on the resist underlayer film. A silicon dioxide film was etched using the resist underlayer film pattern as a mask and using the aforementioned etching apparatus under the conditions of CF₄=180 sccm, Ar=360 sccm, PRESS.=150 mT, HF RF (high-frequency power for plasma generation)=1,000 W, LF RF (high-frequency power for bias)=1,000 W, DCS=−150 V, RDC (gas center flow ratio)=50%, and 60 seconds, thereby affording a substrate on which a pattern was formed on the silicon dioxide film.

Thereafter, for the substrate on which a pattern was formed on a silicon dioxide film, an image was obtained by enlarging the shape of the resist underlayer film pattern of each line width by a magnification of 250,000 times with a scanning electron microscope (“CG-4000” manufactured by Hitachi High-Technologies Corporation), and then the image was subjected to image processing. Thereby, as shown in the FIG., for the lateral side surface 3a of the resist underlayer film pattern 3 (line pattern) having a length of 1,000 nm, a value of 3 sigma, which was obtained by multiplying a standard deviation by 3, the standard deviation having been calculated from the positions Xn (n=1 to 10) in the line width direction measured at 10 points at intervals of 100 nm and the position Xa of the average value of those positions in the line width direction, was defined as LER (line edge roughness). The LER, which indicates the degree of bending of a resist underlayer film pattern, increases as the line width of the resist underlayer film pattern decreases. The bending resistance was evaluated as “A” (good) when the line width of the film pattern having an LER of 5.5 nm was less than 40.0 nm, “B” (slightly good) when the line width was 40.0 nm or more and less than 45.0 nm, and “C” (poor) when the line width was 45.0 nm or more. In the FIG., the degree of bending of a film pattern is illustrated with exaggeration than actual one.

TABLE 2

| | | Etching | Heat | Bending |
|---|---|---|---|---|
| | Composition | resistance | resistance | resistance |
| Example 1 | J-1 | A | A | B |
| Example 2 | J-2 | A | A | B |
| Example 3 | J-3 | A | A | A |
| Example 4 | J-4 | A | A | B |
| Example 5 | J-5 | A | A | B |
| Example 6 | J-6 | A | A | B |
| Example 7 | J-7 | A | B | A |
| Example 8 | J-8 | A | B | B |
| Example 9 | J-9 | A | B | A |
| Example 10 | J-10 | A | B | B |
| Comparative | CJ-1 | C | C | C |
| Example 1 | | | | |
| Comparative | CJ-2 | — | B | C |
| Example 2 | | | | |

As can be seen from the results in Table 2, the resist underlayer films formed from the compositions of Examples were superior in etching resistance, heat resistance, and bending resistance to the resist underlayer films formed from the compositions of Comparative Examples.

The composition of the present disclosure can form a resist underlayer film superior in etching resistance, heat resistance, and bending resistance. The resist underlayer film of the present disclosure is superior in etching resistance, heat resistance, and bending resistance. Using the method for manufacturing a semiconductor substrate of the present disclosure, a favorably-patterned substrate can be obtained. Therefore, they can suitably be used for, for example, producing semiconductor devices expected to be further microfabricated in the future.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A method for manufacturing a semiconductor substrate, the method comprising:
forming a resist underlayer film directly or indirectly on a substrate by applying a composition for forming a resist underlayer film;
forming a resist pattern directly or indirectly on the resist underlayer film; and
performing etching using the resist pattern as a mask,
wherein the composition for forming a resist underlayer film comprises:
a compound comprising: at least one nitrogen-containing ring structure selected from the group consisting of a pyridine ring structure and a pyrimidine ring structure; and a partial structure represented by formula (1-1) or (1-2); and
a solvent, 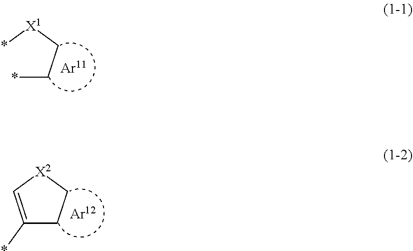
in the formulas (1-1) and (1-2), X¹ and X² are each independently a group represented by formula (i), (ii), (iii), or (iv); * is a bond with a moiety of the compound other than the partial structure represented by formula (1-1) or (1-2); and Ar¹¹ and Ar¹² are each independently a substituted or unsubstituted aromatic ring having 5 to 20 ring members that forms a fused ring structure together with the two adjacent carbon atoms in the formulas (1-1) and (1-2), 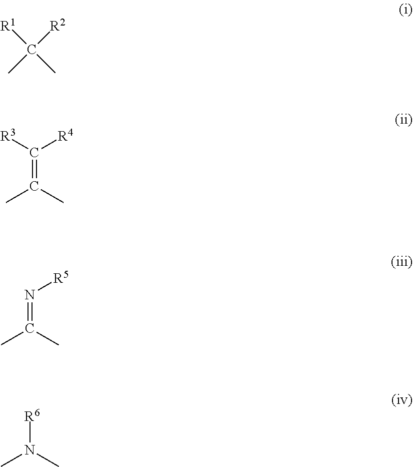
in the formula (i), R¹ and R² are each independently a hydrogen atom or a monovalent organic group having 1 to 20 carbon atoms;
in the formula (ii), R³ and R⁴ are each independently a hydrogen atom or a monovalent organic group having 1 to 20 carbon atoms;
in the formula (iii), R⁵ is a monovalent organic group having 1 to 20 carbon atoms; and
in the formula (iv), R⁶ is a hydrogen atom or a monovalent organic group having 1 to 20 carbon atoms.

2. The method according to claim 1, further comprising:
heating the resist underlayer film at 250° C. or higher before forming the resist pattern.

3. The method according to claim 1, further comprising:
forming a silicon-containing film directly or indirectly on the resist underlayer film before forming the resist pattern.

4. The method according to claim 1, wherein the compound comprises a group represented by formula (X-1), a group represented by formula (X-2), or both, 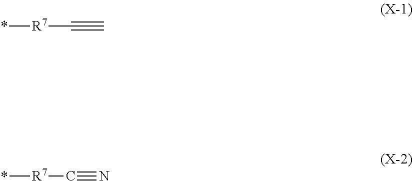
in the formulas (X-1) and (X-2), R⁷ is each independently a divalent hydrocarbon group having 1 to 18 carbon atoms or a single bond; and * is a bond with a carbon atom in the compound.

5. The method according to claim 4, wherein the compound comprises at least one group represented by formula (X-1).

6. The composition according to claim 4, wherein at least one of R¹ and R² in the formula (i), at least one of R³ and R⁴ in the formula (ii), R⁵ in the formula (iii), and R⁶ in the formula (iv) are each independently a group represented by formula (X-1) or (X-2).

7. The composition according to claim 5, wherein at least one of R¹ and R² in the formula (i), at least one of R³ and R⁴ in the formula (ii), R⁵ in the formula (iii), and R⁶ in the formula (iv) are each independently a group represented by formula (X-1) or (X-2).

8. The composition according to claim 1, wherein the compound is represented by formula (2-1), (2-2), or (2-3), 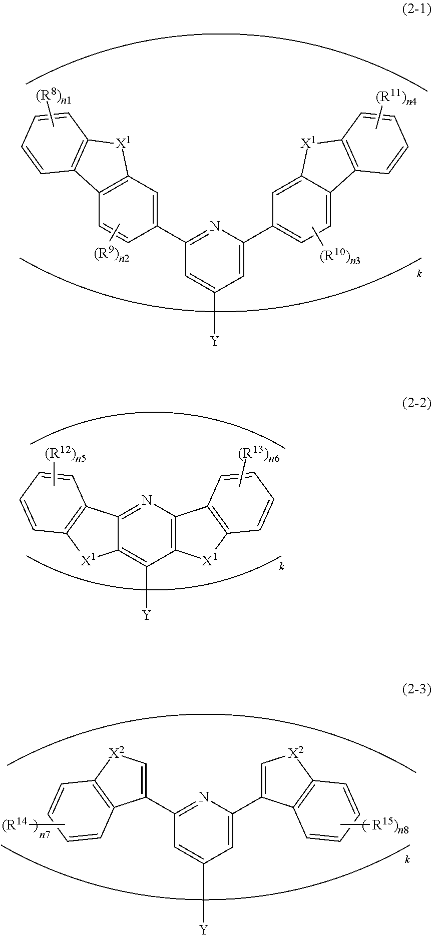
in the formulas (2-1), (2-2), and (2-3), X¹ and X² are each as defined in the formulas (1-1) and (1-2), respectively; R⁸, R⁹, R¹⁰, R¹¹, R¹², R¹³, R¹⁴, and R¹⁵ are each independently a monovalent organic group having 1 to 10 carbon atoms; when R⁸, R⁹, R¹⁰, R¹¹, R¹², R¹³, R¹⁴, and R¹⁵ are each present in a plurality of numbers, the plurality of R⁸, R⁹, R¹⁰, R¹¹, R¹², R¹³, R¹⁴, and R¹⁵ are each the same or different from each other; n₁, n₄, n₅, n₆, n₇, and n₈ are each independently an integer of 0 to 4, and n₂ and n₃ are each independently an integer of 0 to 3; k is independently at each occurrence 1 or 2; and Y is a k-valent organic group having 1 to 20 carbon atoms.

9. A composition comprising:
a compound comprising: at least one nitrogen-containing ring structure selected from the group consisting of a pyridine ring structure and a pyrimidine ring structure; and a partial structure represented by formula (1-1) or (1-2); and
a solvent, 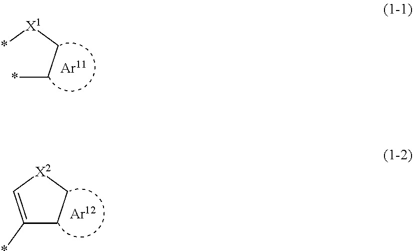
in the formulas (1-1) and (1-2), X¹ and X² are each independently a group represented by formula (i), (ii), (iii), or (iv); * is a bond with a moiety of the compound other than the partial structure represented by formula (1-1) or (1-2); and Ar¹¹ and Ar¹² are each independently a substituted or unsubstituted aromatic ring having 5 to 20 ring members that forms a fused ring structure together with the two adjacent carbon atoms in the formulas (1-1) and (1-2), 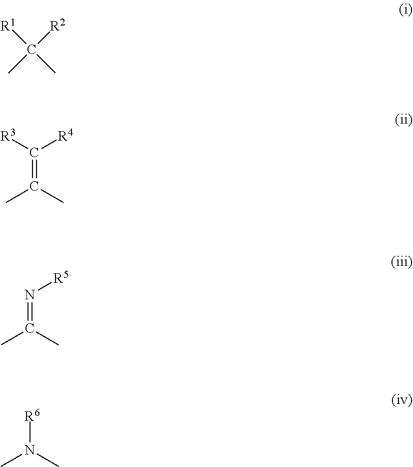
in the formula (i), R¹ and R² are each independently a hydrogen atom or a monovalent organic group having 1 to 20 carbon atoms;
in the formula (ii), R³ and R⁴ are each independently a hydrogen atom or a monovalent organic group having 1 to 20 carbon atoms; R⁴ is a monovalent organic group having 1 to 20 carbon atoms;
in the formula (iii), R⁵ is a monovalent organic group having 1 to 20 carbon atoms; and
in the formula (iv), R⁶ is a hydrogen atom or a monovalent organic group having 1 to 20 carbon atoms.

10. The composition according to claim 9, wherein the compound comprises a group represented by formula (X-1), a group represented by formula (X-2), or both, 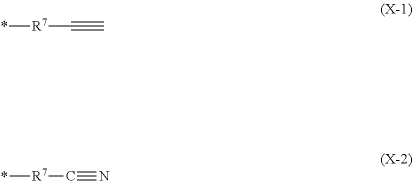
in the formulas (X-1) and (X-2), R⁷ is each independently a divalent hydrocarbon group having 1 to 18 carbon atoms or a single bond; and * is a bond with a carbon atom in the compound.

11. The composition according to claim 10, wherein the compound comprises at least one group represented by formula (X-1).

12. The composition according to claim 10, wherein at least one of R¹ and R² in the formula (i), at least one of R³ and R⁴ in the formula (ii), R⁵ in the formula (iii), and R⁶ in the formula (iv) are each independently a group represented by formula (X-1) or (X-2).

13. The composition according to claim 11, wherein at least one of R¹ and R² in the formula (i), at least one of R³ and R⁴ in the formula (ii), R⁵ in the formula (iii), and R⁶ in the formula (iv) are each independently a group represented by formula (X-1) or (X-2).

14. The composition according to claim 9, wherein the compound is represented by formula (2-1), (2-2), or (2-3), 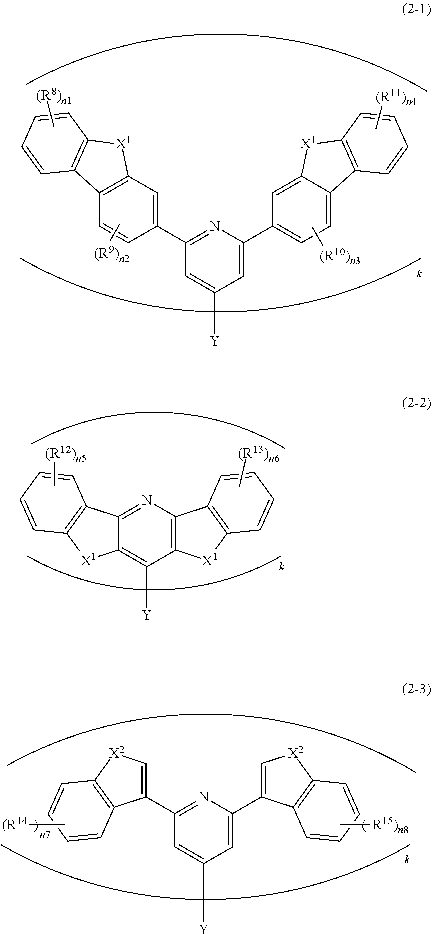
in the formulas (2-1), (2-2), and (2-3), X¹ and X² are each as defined in the formulas (1-1) and (1-2), respectively; R⁸, R⁹, R¹⁰, R¹¹, R¹², R¹³, R¹⁴, and R¹⁵ are each independently a monovalent organic group having 1 to 10 carbon atoms; when R⁸, R⁹, R¹⁰, R¹¹, R¹², R¹³, R¹⁴, and R¹⁵ are each present in a plurality of numbers, the plurality of R⁸, R⁹, R¹⁰, R¹¹, R¹², R¹³, R¹⁴, and R¹⁵ are each the same or different from each other; n₁, n₄, n₅, n₆, n₇, and n₈ are each independently an integer of 0 to 4, and n₂ and n₃ are each independently an integer of 0 to 3; k is independently at each occurrence 1 or 2; and Y is a k-valent organic group having 1 to 20 carbon atoms.

15. The composition according to claim 9, wherein a content ratio of hydrogen atoms to all atoms constituting the compound is 5.5% by mass or less.

16. The composition according to claim 9 that is suitable for forming a resist underlayer film.
